(19) United States
(12) Patent Application Publication
(10) Pub. No.: US 2026/0314382 A1
(43) Pub. Date: Oct. 8, 2026

(54) SEMICONDUCTOR DEVICES HAVING THROUGH-INSULATING STRUCTURES AND DATA STORAGE SYSTEMS INCLUDING THE SAME

(71) Applicant: SAMSUNG ELECTRONICS CO., LTD., Suwon-si (KR)

(72) Inventors: Wooyong JEON, Suwon-si (KR); Youngwoo KIM, Suwon-si (KR)

(73) Assignee: SAMSUNG ELECTRONICS CO., LTD., Suwon-si (KR)

(21) Appl. No.: 19/635,190

(22) Filed: Mar. 31, 2026

(30) Foreign Application Priority Data
Apr. 2, 2025 (KR) 10-2025-0043038

(51) Int. Cl. H10W 20/41; H10B 41/10; H10B 41/27; H10B 41/35; H10B 41/41; H10B 43/10; H10B 43/27; H10B 43/35; H10B 43/40; H10B 80/00; H10D 30/01; H10D 30/68; H10D 30/69; H10D 80/30; H10W 20/00; H10W 20/43; H10W 90/00

(52) U.S. Cl. CPC H10W 20/435; H10B 41/10; H10B 41/27; H10B 41/35; H10B 41/41; H10B 43/10; H10B 43/27; H10B 43/35; H10B 43/40; H10D 30/689; H10D 30/693; H10W 20/43; H10B 80/00; H10D 30/0411; H10D 30/0413; H10D 80/30; H10W 20/076; H10W 90/792

(57) ABSTRACT

A semiconductor device includes a substrate including a first region, a second region and a third region; a stack structure including gate electrodes including lower gate electrodes, memory gate electrodes and upper gate electrodes, and interlayer insulating layers; first contact structures extending in the first direction by different lengths by penetrating an uppermost interlayer insulating layer among the interlayer insulating layers, or penetrating at least a portion of the upper gate electrodes, and electrically connected to the upper gate electrodes, respectively, in the third region, wherein each of the first contact structures includes a through-insulating structure extending and penetrating at least a portion of the upper gate electrodes and in contact with an upper surface of the allocated upper gate electrode; and a first stud penetrating the through-insulating structure and in electrically contact with the upper surface of the allocated upper gate electrode.

### CROSS-REFERENCE TO RELATED APPLICATION(S)

This application claims benefit of priority to Korean Patent Application No. 10-2025-0043038 filed on Apr. 2, 2025 in the Korean Intellectual Property Office, the disclosure of which is incorporated herein by reference in its entirety.

### BACKGROUND

Example embodiments of the present disclosure relate to a semiconductor device having through-insulating structures and a data storage system including the same.

A semiconductor device able to store high-capacity data in a data storage system requiring data storage has been required. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

An example embodiment of the present disclosure is to provide a semiconductor device having improved integration density, which may simplify a manufacturing process thereof.

An example embodiment of the present disclosure is to provide a data storage system including a semiconductor device having improved integration density, which may simplify a manufacturing process therefor.

In example embodiments of the present disclosure, a semiconductor device includes a substrate including a first region, a second region and a third region between the first region and the second region; a stack structure including gate electrodes including lower gate electrodes, memory gate electrodes and upper gate electrodes sequentially stacked and spaced apart from each other in a first direction perpendicular to an upper surface of the substrate,, and interlayer insulating layers disposed alternately with the gate electrodes, in the first region, the second region and the third region; a channel structure penetrating the stack structure and extending in the first direction in the first region; support structures penetrating the stack structure and extending in the first direction in the third region; first contact structures extending in the first direction by different lengths by penetrating an uppermost interlayer insulating layer among the interlayer insulating layers, or penetrating at least a portion of the upper gate electrodes, and electrically connected to the upper gate electrodes, respectively, in the third region; and second contact structures extending from the uppermost interlayer insulating layer in the first direction by different lengths by penetrating the upper gate electrodes and at least a portion of the gate electrodes of the memory gate electrodes and the lower gate electrodes, and electrically connected to the lower gate electrodes and the memory gate electrodes, respectively, in the second region. Each of the first contact structures includes a through-insulating structure extending in the first direction and penetrating the uppermost interlayer insulating layer or penetrating at least a portion of the upper gate electrodes and in contact with an upper surface of an allocated upper gate electrode among the upper gate electrodes; and a first stud extending in the first direction by penetrating the through-insulating structure and in contact with the upper surface of the allocated upper gate electrode, and a portion of the support structures is in contact with at least a portion of the through-insulating structure.

In example embodiments of the present disclosure, a semiconductor device includes a substrate including a first region, a second region and a third region between the first region and the second region; a stack structure including gate electrodes including lower gate electrodes, memory gate electrodes and upper gate electrodes sequentially stacked and spaced apart from each other in a first direction perpendicular to an upper surface of the substrate,, and interlayer insulating layers disposed alternately with the gate electrodes, in the first region, the second region and the third region; a channel structure penetrating the stack structure and extending in the first direction in the first region; support structures penetrating the stack structure, extending in the first direction in the third region, and spaced apart from each other by a first distance; first contact structures extending in the first direction by different lengths by penetrating an uppermost interlayer insulating layer among the interlayer insulating layers, or penetrating at least a portion of the upper gate electrodes, electrically connected to the upper gate electrodes, respectively, and having an upper surface having a first width, in the third region; and second contact structures extending from the uppermost interlayer insulating layer in the first direction by different lengths by penetrating the upper gate electrodes and at least a portion of the gate electrodes the memory gate electrodes and the lower gate electrodes, and electrically connected to the lower gate electrodes and the memory gate electrodes, respectively, in the second region, in which the first width of the first contact structures is greater than the first distance.

In example embodiments of the present disclosure, a data storage system includes a semiconductor storage device including a first semiconductor structure including circuit devices, a second semiconductor structure disposed on one surface of the first semiconductor structure, and an input/output pad electrically connected to the circuit devices; and a controller electrically connected to the semiconductor storage device through the input/output pad and controlling the semiconductor storage device. The second semiconductor structure includes a substrate including a first region, a second region and a third region between the first region and the second region; a stack structure including gate electrodes including lower gate electrodes, memory gate electrodes and upper gate electrodes sequentially stacked and spaced apart from each other in a first direction perpendicular to an upper surface of the substrate, and interlayer insulating layers disposed alternately with the gate electrodes, in the first region, the second region and the third region; a channel structure penetrating the stack structure and extending in the first direction in the first region; support structures penetrating the stack structure, extending in the first direction, and spaced apart from each other by a first distance, in the third region; first contact structures extending in the first direction by different lengths by penetrating an uppermost interlayer insulating layer among the interlayer insulating layers, or penetrating at least a portion of the upper gate electrodes, electrically connected to the upper gate electrodes, respectively, and having an upper surface having a first width, in the third region; and second contact structures extending from the uppermost interlayer insulating layer in the first direction by different lengths by penetrating the upper gate electrodes and at least a portion of the gate electrodes of the memory gate electrodes and the lower gate electrodes, and electrically connected to the lower gate electrodes and the memory gate electrodes, respectively, in the second region, in which the first width of the first contact structures is greater than the first distance.

In example embodiments of the present disclosure, a method of manufacturing a semiconductor device includes forming a mold structure including a first region, a second region, and a third region between the first region and the second region by alternately stacking sacrificial insulating layers and interlayer insulating layers on a substrate in a first direction perpendicular to an upper surface of the substrate; forming first contact holes having different depths in the third region by removing an uppermost interlayer insulating layer of the interlayer insulating layers in the first direction or by removing upper sacrificial insulating layers of at least a portion of the sacrificial insulating layers; forming through-insulating structures burying the first contact holes; forming vertical sacrificial structures cutting at least a portion of the through-insulating structures; removing the vertical sacrificial structures and forming support structures; forming gate electrodes including lower gate electrodes, memory gate electrodes and upper gate electrodes sequentially stacked and spaced apart from each other in the first direction by removing the sacrificial insulating layers; and forming first studs penetrating the through-insulating structures and in contact with one of allocated upper gate electrodes.

The through-insulating structure may include an upper surface; a lower surface in contact with the allocated upper gate electrode; an inner side surface in contact with the first stud between the upper surface and the lower surface; and an outer side surface in contact with the interlayer insulating layers and/or the upper gate electrodes, in which a side surface of each of the first studs may be physically spaced apart from the interlayer insulating layer and the upper gate electrodes.

The forming first studs may include forming a center of an upper surface of the first studs and a center of an upper surface of the through-insulating structure to be coaxial with each other.

The forming the first contact holes may include performing at least one photo-etching process depending on a level of the allocated upper gate electrode.

The forming the support structure may include forming a channel structure in the first region and forming a dummy channel structure having the same shape as a shape of the channel structure as the support structure in the third region.

The forming the first contact holes may include etching to expose an upper surface of a sacrificial insulating layer allocated from the upper surface of the mold structure.

The method may further include forming an upper insulating layer on the stack structure.

The first studs may be formed to penetrate the upper insulating layer and the through-insulating structure together.

A width of an upper surface of the first studs may be less than ⅓ to ¼ of a width of the through-insulating structures.

The forming a first contact hole may include forming the first contact hole to have a first distance such that mold structures may be disposed between the first contact holes.

The forming the support structures may include forming the support structures such that ½ or less of a circumference of an upper surface may protrude to the through-insulating structure.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to example embodiments of the present disclosure;

FIG. 2A and FIG. 2B are cross-sectional diagrams illustrating a semiconductor device according to example embodiments of the present disclosure;

FIG. 3A, FIG. 3B, and FIG. 3C are enlarged diagrams illustrating a partial region in FIG. 2A and FIG. 2B;

FIG. 4 and FIG. 5 are enlarged cross-sectional diagrams illustrating a semiconductor device according to example embodiments of the present disclosure;

FIG. 6 and FIG. 7 are diagrams illustrating a semiconductor device according to example embodiments of the present disclosure, viewed from above;

FIG. 8 is a cross-sectional diagram illustrating the semiconductor device illustrated in FIG. 7;

FIG. 9 is a diagram illustrating a semiconductor device according to example embodiments of the present disclosure, viewed from above;

FIG. 10, FIG. 11, and FIG. 12 are cross-sectional diagrams illustrating a semiconductor device according to example embodiments of the present disclosure;

FIGS. 13A-13I and 14A-14D are cross-sectional diagrams illustrating a method of manufacturing a semiconductor device according to example embodiments of the present disclosure;

FIG. 15 is a diagram illustrating a data storage system including a semiconductor device in example embodiments of the present disclosure; and

FIG. 16 is a perspective diagram illustrating a data storage system including a semiconductor device in example embodiments of the present disclosure.

### DETAILED DESCRIPTION

Hereinafter, embodiments of the present disclosure will be described as follows with reference to the accompanying drawings.

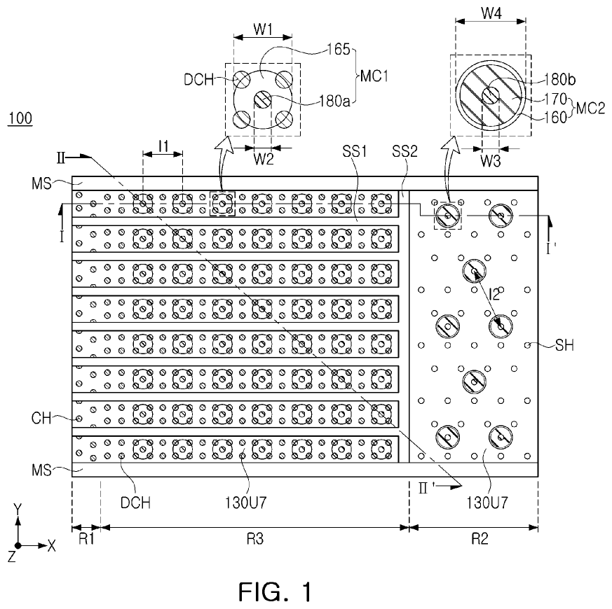

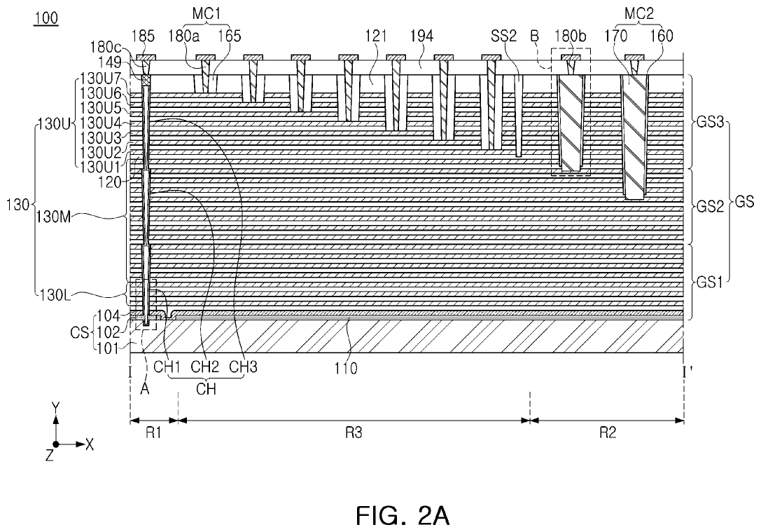

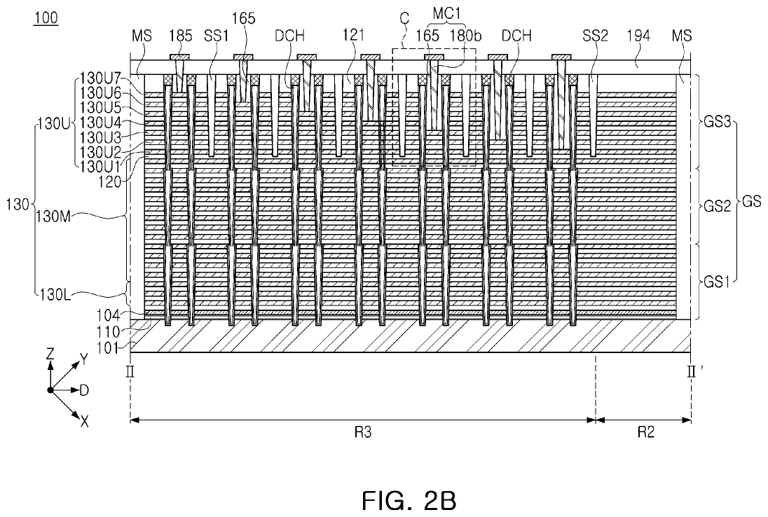

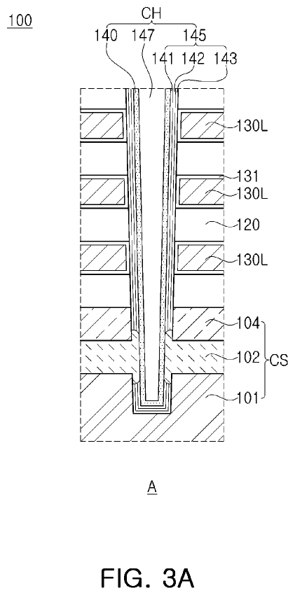

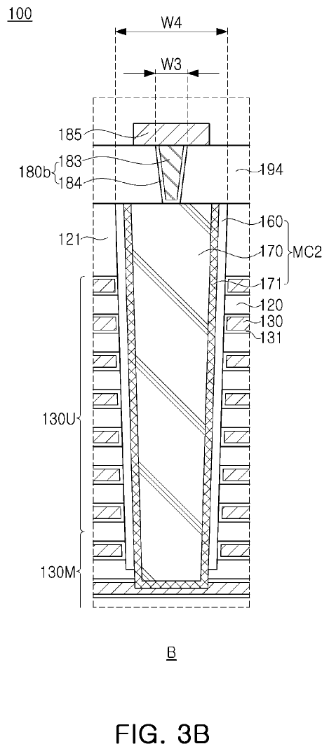

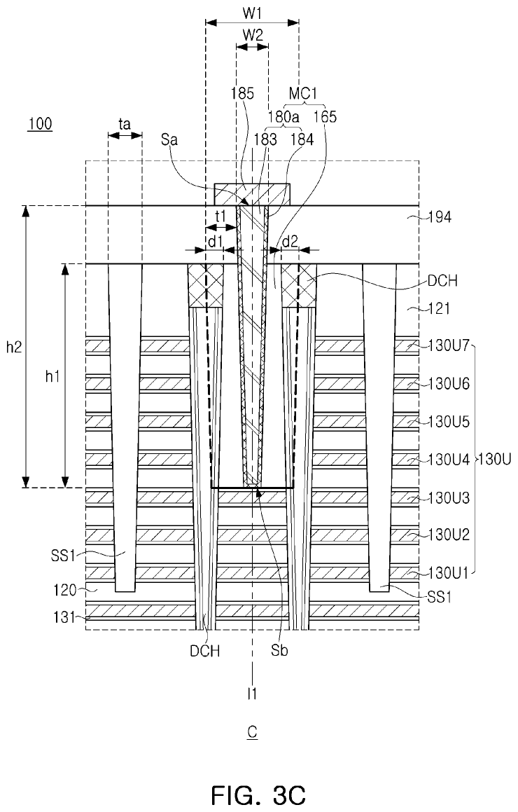

Hereinafter, a semiconductor device according to example embodiments will be described with reference to FIG. 1, FIG. 2A, FIG. 2B, FIG. 3A, FIG. 3B and FIG. 3C.

FIG. 1 is a plan diagram illustrating a semiconductor device according to example embodiments. FIGS. 2A and 2B are cross-sectional diagrams illustrating a semiconductor device according to example embodiments. FIG. 2A is a cross-sectional diagram illustrating a region of the semiconductor device in FIG. 1 taken along line I-I′, and FIG. 2B is a cross-sectional diagram illustrating a region of the semiconductor device in FIG. 1 taken along line II-II′. FIG. 3A is an enlarged diagram illustrating region ‘A’ in FIG. 2A, FIG. 3B is an enlarged diagram illustrating region ‘B’ in FIG. 2A, and FIG. 3C is an enlarged diagram illustrating region ‘C’ in FIG. 2B.

Referring to FIGS. 1, 2A, 2B, 3A, 3B and 3C, a semiconductor device 100 may include a memory region R1 and an extension region R2 to one side of the memory region R1 in the X-direction.

The memory region R1 may be a memory cell region in which memory cell strings are disposed, and channel structures CH may be disposed in the memory region R1. The extension region R2 may correspond to an area that electrically connects the channel structures CH to peripheral circuit structures. To this end, a plurality of wordline contact structures MC2, which are connected to gate electrodes 130 at different levels, may be disposed in the extension region R2. However, an example embodiment is not limited to this configuration.

An upper contact region R3 may be disposed between the memory region R1 and the extension region R2. In the upper contact region R3, upper contact structures MC1 connected to upper gate electrodes 130U may be disposed. The upper contact region R3 may be defined as a region in which the upper contact structures MC1 for connecting erase gate electrodes 130U7-130U5 to a string select line, i.e., string select gate electrodes 130U4-130U1, are disposed.

More specifically, the upper contact region R3 may be adjacent to the memory region R1, and the upper contact structures MC1 connected to the erase gate electrodes 130U7-130U5 and the string select gate electrodes 130U4-130U1 may be disposed in the upper contact region R3. In this region, the upper gate electrodes 130U may not form a staircase structure. Instead, the upper gate electrodes 130U may extend flatly from the memory region R1 to the extension region R2, passing through the upper contact region R3.

In the upper contact region R3, only the contact regions of the upper gate electrodes 130U that are connected to the upper contact structures MC1 may be exposed in a through-insulating structure 165. In the contact region, the upper gate electrodes 130U may be in direct physical and electrical contact with first studs 180a of the upper contact structures MC1, respectively.

The semiconductor device 100 may have a structure in which the memory region R1, the upper contact region R3, and the extension region R2 are consecutively arranged in the X-direction.

The semiconductor device 100 may include a semiconductor substrate 101 extending through the memory region R1, the upper contact region R3, and the extension region R2; stack structures (GS1-GSk; k is a positive integer) comprising gate electrodes 130 and interlayer insulating layers 120 alternately stacked on the upper surface of the substrate 101; channel structures CH penetrating the stack structures GS1-GSk in the memory region R1; isolation regions MS extending in the X-direction and penetrating the stack structures GS1-GSk; and insulating regions SS1 and SS2 penetrating at least a portion of the gate electrodes 130. An interconnection structure and a passivation layer may be further included beneath the substrate 101.

Support structures SH and wordline contact structures MC2 may be disposed in the extension region R2.

Dummy channel structures DCH and upper contact structures MC1 may be disposed in the upper contact region R3, between the memory region R1 and the extension region R2.

In FIGS. 2A, 2B, 3A, 3B and 3C, the contact structures MC1 and MC2 may have different lengths to establish electrical connection between the gate electrode 130 and the respective contact structures MC1 and MC2, but an example embodiment is not limited to these configurations.

The memory region R1 through the extension region R2 may penetrate an upper insulating layer 194, which constitutes an upper portion of the stack structure GS. The upper insulating layer 194 may include second and third studs 180b and 180c for electrical connection with the channel structure CH and the wordline contact structures MC2, respectively, and a cell interconnection line 185 formed on the upper insulating layer 194.

The substrate 101 may include at least one of a conductive material, such as doped silicon, or a conductive material, such as a metal (or a metal nitride), to function as a common source line. For example, the substrate 101 may include a semiconductor material such as a group IV semiconductor, a group III-V compound semiconductor, or a group II-VI compound semiconductor. The substrate 101 may be provided as a bulk wafer or an epitaxial layer.

The semiconductor device 100 may further include first and second horizontal conductive layers 102 and 104, a horizontal insulating layer 110, and a substrate insulating layer.

The first and second horizontal conductive layers 102 and 104 may be sequentially stacked on an upper surface of the substrate 101 in the memory region R1. The first and second horizontal conductive layers 102 and 104, together with the substrate 101, may form a common source structure CS and may function as a common source line of the semiconductor device 100. As illustrated in FIG. 3A, the first horizontal conductive layer 102 may be directly connected to a channel layer 140 in a lower portion of the channel structures CH. The first and second horizontal conductive layers 102 and 104 may include a semiconductor material, for example, polycrystalline silicon. In this case, at least the first horizontal conductive layer 102 may be doped with impurities of the same conductivity-type as the substrate 101.

The horizontal insulating layer 110 may be disposed on the substrate 101, at the same level as the first horizontal conductive layer 102, in at least a portion of the upper contact region R3 and the extension region R2. The horizontal insulating layer 110 may include first and second horizontal insulating layers alternately stacked on the substrate 101. The horizontal insulating layer 110 may be layers remaining after a portion of the first horizontal conductive layer 102 is replaced in the process of manufacturing the semiconductor device 100. The horizontal insulating layer 110 may include silicon oxide, silicon nitride, silicon carbide, or silicon oxynitride. The first horizontal insulating layers and the second horizontal insulating layer may include different insulating materials.

The substrate insulating layer may be disposed to cover a curved portion of the second horizontal conductive layer 104 located between the memory region R1 and the upper contact region R3. In some example embodiments, when a through-electrode extends from a first semiconductor structure S1 to a second semiconductor structure S2, the substrate insulating layer may penetrate the substrate 101, the horizontal insulating layer 110, and the second horizontal conductive layer 104. The through-electrode may further penetrate the substrate insulating layer.

The gate electrodes 130 may be vertically spaced apart from each other on the upper surface of the substrate 101, and may be included in the stack structure GS (GS1-GS3) along with the interlayer insulating layers 120.

Throughout the entire stack structures GS, the gate electrodes 130 may include at least one lower gate electrode 130L forming a gate of a ground select transistor; a plurality of memory gate electrodes 130M forming a plurality of memory cells; and a plurality of upper gate electrodes 130U functioning as string select lines forming gates of string select transistors. Here, the lower gate electrode 130L and the upper gate electrodes 130U may be referred to as “lower” and “upper” based on the direction during the manufacturing process. The number of the memory gate electrodes 130M forming memory cells may be determined depending on capacity of the semiconductor device 100. In example embodiments, one or two (or more) upper and lower gate electrodes 130U and 130L may be included, having either the same or a different structure from the memory gate electrodes 130M. In an example embodiment, the upper gate electrodes 130U may include seven electrodes: three erase gate electrodes 130U7-130U5, and four string select gate electrodes 130U4-130U1, arranged in descending order. A portion of the gate electrodes 130, such as the memory gate electrodes 130M adjacent to the upper or lower gate electrode 130U and 130L, may be dummy gate electrodes 130, but an example embodiment thereof is not limited thereto.

The gate electrodes 130 may extend from the extension region R2 to the memory region R1 on one side, and may be stacked such that each gate electrode 130 has a flat upper surface parallel to the upper surface of the substrate 101, without forming a staircase or step structure. Accordingly, the area of each gate electrode 130 may be substantially uniform.

The stack structure GS may include multiple levels of stack structures GS1-GS3 stacked in the Z-direction. In FIGS. 2A and 2B, three stack structures GS1, GS2, and GS3 are illustrated, but an example embodiment thereof is not limited thereto. In other embodiments, four to eight levels of stack structure GS may be included, or in some cases, only two. Each level of stack structure GS may be classified by the height necessary for forming a channel hole with a predetermined depth, corresponding to channel portions CH1, CH2, and CH3 of a channel structure CH. The lower stack structure positioned on the upper surface of the substrate 101 may be referred to as the first stack structure GS1, and the stack structures GS2-GS3 on the first stack structure GS1 may be referred to as the second stack structure GS2, and the third stack structure GS3 sequentially.

In the stack structures GS1-GS3, gate electrodes 130 and interlayer insulating layers 120 may be alternately stacked in the Z-direction. The height of each of the stack structure GS1-GS3 in the Z-direction and the number of the gate electrodes 130 may be substantially the same, but an example embodiment thereof is not limited thereto.

Referring to FIGS. 1, 2A and 2B, the gate electrodes 130 may be isolated from each other in the Y-direction by isolation regions MS extending continuously from the memory region R1 to the extension region R2. The gate electrodes 130 positioned between a pair of isolation regions MS may be included in a single memory block BLK, but the range of the memory block BLK is not limited thereto. A portion of the gate electrodes 130, such as the memory gate electrodes 130M, may be grouped into one layer within the same memory block BLK.

The gate electrodes 130 may be vertically stacked and spaced apart from each other in the Z-direction across the memory region R1, the upper contact region R3, and the extension region R2, and may maintain a continuous plate shape without forming a stepped or staircase configuration in the upper contact region R3 or the extension region R2. Accordingly, a portion of each gate electrode 130 may be defined as contact regions for the first studs 180a via the upper contact structure MC1 in the upper contact region R3, and as contact regions for the wordline contact structures MC2 in the extension region R2.

The gate electrodes 130 may include a conductive material layer. For example, the conductive material layer may be formed of tungsten (W), ruthenium (Ru), molybdenum (Mo), niobium (Nb), nickel (Ni), cobalt (Co), titanium (Ti), tantalum (Ta), titanium nitride (TiN), tantalum nitride (TaN), tungsten nitride (WN), niobium nitride (NbN), titanium aluminum (TiAl), titanium aluminum nitride (TiAlN), titanium silicide (TiSi), titanium silicide nitride (TiSiN), tantalum silicide (TaSi), tantalum silicide nitride (TaSiN), ruthenium titanium nitride (RuTiN), nickel silicide (NiSi), cobalt silicide (CoSi) or a combination thereof, but an example embodiment thereof is not limited thereto. According to example embodiments, the gate electrodes 130 may further include a diffusion barrier 131, which may include, e.g., WN, TaN, TiN or a combination thereof.

The interlayer insulating layers 120 may be disposed between the gate electrodes 130 and may be included in the stack structure GS. The interlayer insulating layers 120 may be disposed so as to be spaced apart from each other in Z-direction perpendicular to the upper surface of the substrate 101 and to extend in the X-direction, similarly to the gate electrodes 130. The interlayer insulating layers 120 may include an insulating material such as silicon oxide or silicon nitride.

In example embodiments, the interlayer insulating layers 120 may have substantially the same thickness, although variations are possible. For example, the uppermost interlayer insulating layer 121 of the interlayer insulating layers 120 may have a thickness greater than a thickness of the other interlayer insulating layers 120, but an example embodiment thereof is not limited thereto. In the above description, the semiconductor device 100 may be described as including the memory region R1, the upper contact region R3, and the extension region R2, but the stack structure GS may include the memory region R1, the upper contact region R3, and the extension region R2.

The isolation regions MS may penetrate at least a portion of the gate electrodes 130 and may extend in the X-direction. The isolation regions MS may span continuously across the memory region R1, the upper contact region R3, and the extension region R2, and may be arranged in parallel to each other in the X-direction. The isolation regions MS may penetrate the entire stacked gate electrodes 130 and may be connected to the substrate 101. The isolation regions MS may extend in the X-direction as an integrated region, or may extend intermittently in partial portions, or may be disposed only in a partial region. The isolation regions MS may have a line shape on the X-Y plane, or may have a shape in which a side surface may have a continuous curve and may extend in the X-direction.

An isolation insulating layer may be disposed in the isolation regions MS. The isolation insulating layer may have a shape of which a width decreases toward the substrate 101 due to a high aspect ratio, but an example embodiment thereof is not limited thereto. An upper surface of the isolation insulating layer may be in contact with the upper insulating layer 194, and the lower surface may be in contact with the upper surface of the substrate 101.

The insulating regions SS1 and SS2 may extend in the X-direction between the adjacent isolation regions MS. The insulating regions SS1 and SS2 may selectively penetrate only the upper gate electrodes 130U1-130U7, that is, the erase gate electrodes 130U7-130U5, and the string select lines 130U4-130U1, and may divide the upper gate electrodes 130U into a plurality of sub-regions within the stack structure GS.

Referring to FIG. 1, the first insulating regions SS1 may extend across both the memory region R1 and the upper contact region R3 in the X-direction. The first insulating regions SS1 may be parallel to each other between the isolation regions MS, and may be spaced apart from each other in the Y-direction. The second insulating region SS2 may be disposed between the upper contact region R3 and the extension region R2, and may extend in the Y-direction. The upper gate electrodes 130U may be divided into a plurality of sub-regions by the first insulating regions SS1, the isolation region MS, and the second insulating region SS2, and only the channel structures CH of the corresponding sub-regions may be selected depending on a voltage level of the upper gate electrodes 130U of the corresponding sub-regions.

The first and second insulating regions SS1 and SS2 may be disposed to have the same length in the Z-direction from an upper portion, and may be disposed at a level lower than a level of the lower surface of the lowermost upper gate electrode 130U1 among the upper gate electrodes 130U, and may be disposed at a level higher than a level of the lower surface of the interlayer insulating layer 120 below the lowermost upper gate electrode 130U1. Accordingly, the upper gate electrodes 130U may be completely penetrated and isolated by the first and second insulating regions SS1 and SS2, and may include a plurality of sub-regions physically/electrically completely spaced apart from each other. The upper contact region R3 may have a plate shape in which each of the upper gate electrodes 130U may have no step difference in each sub-region.

The first and second insulating regions SS1 and SS2 may selectively penetrate only the upper gate electrode 130U and may not extend below the memory gate electrode 130M, such that the memory gate electrodes 130M and the lower gate electrodes 130L may not be isolated from each other by the insulating regions SS1 and SS2. As a result, the memory gate electrodes 130M and the lower gate electrodes 130L may be individually stacked in an integrated plate shape up to the memory region R1, the upper contact region R3, and the extension region R2.

The first insulating regions SS1 may be disposed across a portion of the channel structures CH in the memory region R1. The first insulating regions SS1 may have a predetermined width and may extend across the plurality of channel structures CH arranged in a zigzag pattern along the X-direction. Accordingly, when the plurality of channel structures CH are uniformly spaced, the first insulating regions SS1 may extend while cutting at least a portion of the channel structures CH. The first insulating regions SS1 may be recessed into an upper end of the channel structures CH, for example, a portion of the channel structures CH facing the seven upper gate electrodes 130U, and accordingly, a portion of the channel structures CH may be removed. In this case, the channel structures CH may be recessed to cut ⅓ to ¼ of a circumference of the upper surface when viewed on the X-Y plane. The first insulating regions SS1 may not pass through the channel central axis of the channel structures CH, and may be disposed such that ⅔ or more of the channel structures CH may remain on the upper surface, but an example embodiment thereof is not limited thereto. The channel structures CH into which the first insulating regions SS1 are recessed may be effective channel structures actually functioning as memory cells, not dummy channel structures. The first insulating regions SS1 may extend in a line shape from the memory region R1 to the upper contact region R3, or may also extend in a wavy shape from the memory region R1

Each of the insulating regions SS1 and SS2 may include an upper isolation insulating layer. The upper isolation insulating layer may include an insulating material, for example, silicon oxide, silicon nitride, or silicon oxynitride.

The channel structures CH may be arranged in rows and columns and spaced apart from each other on the substrate 101 within the memory region R1. In the memory region R1, the channel structures CH may be disposed in a zigzag pattern along one direction on the X-Y plane. The channel structures CH may penetrate the gate electrodes 130, and may extend in a vertical direction perpendicular to the upper surface of the substrate 101, for example, in the Z-direction. The channel structures CH may have a pillar shape, and may have an inclined side surface of which a width decreases toward the substrate 101 depending on an aspect ratio.

Each of the channel structures CH may have a form in which a k number of channel portions CH1-CHk (k is a positive integer such as 1, 2, or 3) penetrating a k number of stack structures GS1-GSk of the gate electrodes 130 are connected to each other. In an example embodiment, the first to third channel portions CH1-CH3 penetrating three stack structures GS1-GS3 may be connected to each other.

As illustrated in the enlarged diagram in FIG. 3A, each of the first to third channel portions CH1-CH3 may have an upper end having a width greater than a width of a lower end. Each side surface may have an inclined surface of which a width decreases toward the substrate 101 due to the difference in width between the upper end and the lower end. The lower end of the channel portions CH1-CH3 in an upper portion and the upper end of the channel portions CH1-CH3 in a lower portion may be connected to each other and may form a bent portion.

Each of the channel structures CH may include a first portion in the stack structure GS1-GS3, and a second portion protruding below the stack structure GS1-GS3 and in contact with the substrate 101.

The channel layer 140 may be disposed entirely in the channel structures CH, and may have a side surface having an annular shape surrounding a buried insulating layer 147 therein, or may also have a pillar shape such as a cylindrical or prism shape without the buried insulating layer 147 in example embodiments. The channel layer 140 may include a semiconductor material such as polycrystalline silicon or single crystal silicon, and the semiconductor material may be an undoped material or a material including P-type or N-type impurities.

Channel pads 149 may be disposed in an upper portion of the channel layer 140 in the channel structures CH. The channel pads 149 may cover an upper surface of the buried insulating layer 147 and may be electrically connected to the channel layer 140. The channel pads 149 may include, for example, doped polycrystalline silicon.

A channel dielectric layer 145 may be disposed between the gate electrodes 130 and the channel layer 140. The channel dielectric layer 145 may include a tunneling layer 141, a charge storage layer 142, and a blocking layer 143 stacked in order from the channel layer 140. The tunneling layer 141 may tunnel electric charge into the charge storage layer 142, which may include, for example, silicon oxide (SiO₂), silicon nitride (Si₃N₄), silicon oxynitride (SiON), or a combination thereof. The charge storage layer 142 may be an electric charge trap layer or a floating gate conductive layer. The blocking layer 143 may include silicon oxide (SiO₂), silicon nitride (Si₃N₄), silicon oxynitride (SiON), a high-κ dielectric material, or a combination thereof. According to example embodiments, at least a portion of the channel dielectric layer 145 may extend horizontally along the gate electrodes 130.

A portion of the channel dielectric layer 145 may be removed such that the substrate conductive layer 102 may be in direct contact with the channel layer 140.

The channel layer 140, the channel dielectric layer 145, and the buried insulating layer 147 may be connected to each other between the first to third channel portions CH1-CH3.

Dummy channel structures DCH may be disposed in the upper contact region R3. These structures may be identical or similar in form to channel structures CH, but they do not function as actual memory in the semiconductor device 100. The dummy channel structures DCH may be disposed regularly in columns and rows in the upper contact region R3. The arrangement of dummy channel structures DCH may be different from the arrangement of channel structures CH. For example, the dummy channel structures DCH may be arranged in a checkerboard pattern, and the channel structures CH may be arranged in a zigzag pattern. Also, a spacing distance Id between dummy channel structures DCH may be greater than the spacing distance between channel structures CH.

In FIG. 1, dummy channel structures DCH are illustrated as being disposed to form two rows in each sub-region, but an example embodiment thereof is not limited. thereto.

A portion of the dummy channel structures DCH of the dummy channel structures DCH may surround the upper contact structures MC1. As illustrated in FIG. 1, four dummy channel structures DCH may be disposed around one upper contact structure MC1, and at least a portion of the dummy channel structures DCH around the upper contact structure MC1 may overlap the upper contact structure MC1. A portion of the dummy channel structures DCH may penetrate the stack structure GS disposed in a spacing between the adjacent upper contact structures MC1.

The channel structures CH and the dummy channel structures DCH may have a circular shape or a shape similar to a circular shape, although other shapes, such as elliptical, are also possible. The dummy channel structures DCH may penetrate the stack structure GS similarly to the channel structures CH, and the channel dielectric structure 145 may be disposed in the region in contact with the substrate 101 and the horizontal insulating layer 110, such that the channel layer 140 may not be exposed, and thus, an insulating state with the substrate 101 may be maintained. The dummy channel structures DCH may function as a supporter structure which may prevent deformation such as warpage of the stack structure GS.

Support structures SH may be disposed in the extension region R2. The support structures SH may be insulating structures which may include insulating materials such as oxide, nitride, oxynitride, or oxycarbide, and may have a structure different from the dummy channel structures DCH. The support structures SH may be regularly disposed in columns and rows in the extension region R2. The support structures SH may have a diameter greater than a maximum diameter of the channel structures CH but less than the maximum diameter W4 of the wordline contact structures MC2. The shape, number, and/or distance of the support structures SH may be different. The support structures SH may have a circular shape or a shape similar to a circular shape, but an example embodiment thereof is not limited thereto, the support structures SH may have an elliptical shape. Similarly to the channel structures CH, the support structures SH may have a vertical portion penetrating the stack structure GS and extending in the Z direction, and horizontal portions protruding toward each gate electrode 130 from the vertical portion, but the shape of the support structures SH is not limited thereto. The support structure SH may also have a structure including a plurality of bent portions corresponding to the bent portions of the first to third channel portions CH1-CH3 of the channel structure CH. The support structures SH may be a supporter which may prevent deformation such as warpage of the stack structure GS.

The semiconductor device 100 may include contact structures MC1 and MC2 connected to gate electrodes 130, respectively, in the upper contact region R3 and the extension region R2. The contact structures MC1 and MC2 may penetrate the uppermost interlayer insulating layer 121, may extend downwardly in the Z-direction and may be connected to the upper surface of the allocated gate electrodes 130. The contact structures MC1 and MC2 may have a circular shape or elliptical shape on the X-Y plane as illustrated in FIG. 1, and may be disposed spaced apart from each other in the X-direction and Y-direction. The contact structures MC1 and MC2 may be arranged in a lattice pattern or a zigzag pattern, and the arrangement between the upper contact structures MC1 and the wordline contact structures MC2 and the shapes thereof may be different from each other.

The wordline contact structures MC2 may be alternately arranged in rows in a zigzag pattern in the extension region R2, and the upper contact structures MC1 may be arranged in rows in the sub-regions separated by the isolation regions SS1 and SS2 in the upper contact region R3.

The upper contact structures MC1 may be disposed in the upper contact region R3, and may be connected to a predetermined number of upper gate electrodes 130U functioning as erase gate electrodes 130U7-130U5 among the upper gate electrodes 130U, and a predetermined number of upper gate electrodes 130U functioning as string select lines 130U4-130U1, respectively.

In FIG. 1, FIG. 2A, and FIG. 2B, it is illustrated that three erase gate electrodes 130U7-130U5 are included and four string select lines 130U4-130U1 are included. Accordingly, seven upper contact structures MC1 connected to the upper gate electrode 130U1-130U7 may be disposed in the sub-regions, respectively. That is, seven upper contact structures MC1 connected to the upper gate electrodes 130U, respectively, may be spaced apart from each other in a row by a first distance I1 in the sub-regions of the upper gate electrodes 130U divided by the first and second insulating regions SS1 and SS2.

In an example embodiment, the upper gate electrodes 130U may have a flat upper surface without a step structure of a staircase form in the upper contact region R3, and may be coplanar with the upper surface of the upper gate electrodes 130U in the extension region R2. The upper contact structures MC1 may penetrate from the upper surface of the stack structure GS to an upper portion of the allocated upper gate electrode 130U, and may be in contact with the contact region of the allocated upper gate electrode 130U.

The contact region in the upper gate electrodes 130U may have the same area and shape as those of the lower surface of the upper contact structures MC1, and may be understood as an exposed surface exposed while forming upper contact holes for forming the upper contact structures MC1.

In each sub-region, one upper contact structure MC1 may be connected to one upper gate electrode 130U, or alternatively, a plurality of upper contact structures MC1 may be connected to one upper gate electrode 130U. Accordingly, the number of upper contact structures MC1 allocated to each of the sub-regions may be the same, and the number of upper contact structures MC1 allocated to each of the sub-regions may satisfy an integer multiple of the number of upper gate electrodes 130U.

As illustrated in FIG. 1, when the number of upper contact structures MC1 is the same as the number of upper gate electrodes 130U in each sub-region, the upper contact structures MC1 disposed in the same position in each sub-region may be in contact with the upper gate electrode 130U at the same level.

For example, when the upper contact structure MC1 most adjacent to the channel structure CH is denoted as the first upper contact structure MC1, the first upper contact structure MC1 may be connected to the uppermost upper gate electrode 130U7, and the lower end level of the upper contact structures MC1 may be lowered by one gate electrode 130 toward the extension region R2. The contact direction and the order are not limited thereto, and may vary.

Each of the upper contact structures MC1 may include the through-insulating structure 165 and the first studs 180a.

The through-insulating structure 165 may be a structure burying the entire upper contact holes for opening from the upper surface of the stack structure GS to the upper surface of the allocated upper gate electrode 130U.

Accordingly, the through-insulating structure 165 may include an upper surface coplanar with the upper surface of the stack structure GS, a lower surface in contact with the upper surface of the allocated upper gate electrode 130U, and a side surface between the upper surface and the lower surface. The upper surface of the through-insulating structure 165 may have a circular, elliptical, or polygonal shape, and, for example, the maximum diameter of the upper surface may have a first width W1. The first width W1 of the upper surface may be greater than the width of the lower surface, and accordingly, the side surface may have a slope. The first width W1 of the upper surface may be equal to or less than the fourth width W4 of the upper surface of the wordline contact structures MC2.

The through-insulating structure 165 may be a cylindrical structure having a first thickness t1, and an outer side surface may be in contact with the upper gate electrodes 130U or the interlayer insulating layers 120, and an inner side surface may surround a first stud 180a. The first thickness t1 of the through-insulating structure 165 may be greater than the thickness of the side surface insulating layer 160 of the second contact structure MC2.

The through-insulating structures 165 in a sub-region may have different first lengths h1 in the Z-direction, and the first length h1 of the through-insulating structure 165 may be equal to the length from the upper surface of the stack structure GS to the upper surface of the allocated upper gate electrode 130U.

The through-insulating structures 165 may include an insulating material, and may include at least one of an oxide, an oxycarbide, or an oxynitride. For example, the through-insulating structures may include silicon oxide, may include the same material as the interlayer insulating layer 120, and may be implemented by a material different from silicon nitride forming the sacrificial insulating layer 118.

Each of the upper contact structures MC1 may include a first stud 180a penetrating the through-insulating structure 165 and in direct contact with the upper surface of the allocated upper gate electrode 130U.

The first stud 180a may penetrate the upper insulating layer 194 from the upper surface of the upper insulating layer 194 and may continuously penetrate the through-insulating structure 165. Accordingly, an upper surface Sa of the first stud 180a may be coplanar with an upper surface of a contact region of the upper insulating layer 194, and a lower surface Sb may be in contact with an upper surface of the allocated upper gate electrode 130U. A portion of the first stud 180a may protrude into the allocated upper gate electrode 130U, and the lower surface Sb of the first stud 180a may be positioned at a level lower than a level of the lower surface of the through-insulating structure 165, but an example embodiment thereof is not limited thereto. The upper surface Sa of the first stud 180a may have a second width W2, and the second width W2 may be smaller than the first width W1. For example, the second width W2 may be smaller than ⅓ to ¼ of the first width W1. A second width W2 of the upper surface Sa of the first stud 180a may be greater than the width of the lower surface Sb, and a side surface between the upper surface Sa and the lower surface Sb may have a slope. The second width W2 of the upper surface Sa of the plurality of first studs 180a may be the same, and the widths of the lower surfaces Sb may be different, but an example embodiment thereof is not limited thereto.

The central line l1 passing through a center of the second width W2 of the first stud 180a may be coaxial with the central line l1 passing through a center of the first width W1 of the through-insulating structure 165. Accordingly, the first stud 180a may be understood as being disposed at a center of the through-insulating structure 165.

The side surface of the first stud 180a may be spaced apart from the outer side surface of the through-insulating structure 165, and may be physically and electrically spaced apart from the penetrated upper gate electrodes 130U. The through-insulating structure 165 may be disposed between the first stud 180a and the upper gate electrode 130U.

The first stud 180a may have a second length h2 in the Z-direction, which may be greater than the first length h1. That is, the upper surface Sa of the first stud 180a may be positioned above the upper surface of the through-insulating structure 165, while the lower surface Sb of the first stud 180a may be disposed at or below the lower surface of the through-insulating structure 165, such that the first stud 180a may completely penetrate the through-insulating structure 165.

The first stud 180a may include a contact barrier layer 184 on the lower surface Sb and the side surface, and may include a conductive material layer 183 on the contact barrier layer 184. The conductive material layer 183 may include at least one of tungsten (W), copper (Cu), aluminum (Al), or an alloy thereof. For example, the conductive material layer 183 may include tungsten (W). The contact barrier layer 184 may include tungsten nitride (WN), tantalum nitride (TaN), titanium nitride (TiN), or a combination thereof.

The four dummy channel structures DCH in contact with the upper contact structure MC1 and disposed around the upper contact structure MC1 may be disposed as illustrated in FIG. 1, and at least a portion of the four dummy channel structures DCH may cut a portion of the through-insulating structure 165. As illustrated in FIG. 1, four dummy channel structures DCH may be disposed to have the same spacing distance as the first stud 180a disposed on a center axis l1 of the upper contact structure MC1. Each of the dummy channel structures DCH around the upper contact structure MC1 may be disposed while cutting at least a portion of the upper contact structure MC1.

That is, when the dummy channel structures DCH are spaced apart from each other so as to have a spacing distance Id, the first width W1 of the upper surface of the through-insulating structure 165 of the upper contact structure MC1 may be greater than the spacing distance Id. Accordingly, at least one dummy channel structure DCH may be disposed to overlap or intersect a portion of the through-insulating structure 165, thereby partially cutting into a portion of the through-insulating structure 165.

Referring to FIG. 3C, the upper surface of the dummy channel structures DCH may be coplanar with the upper surface of the through-insulating structure 165, and may extend toward the substrate 101 while cutting the through-insulating structure 165 such that ½ to ¼ of the circumference of the upper surface of the dummy channel structures DCH may protrude to the through-insulating structure 165.

The protruding lengths d1 and d2 of the dummy channel structures DCH protruding into the through-insulating structure 165 may be different for each of the dummy channel structures DCH. For example, the protruding length d1 of the dummy channel structures DCH disposed on the left side of the first stud 180a may be different from the protruding length d2 of the dummy channel structures DCH disposed on the right side.

The side surface of the dummy channel structure DCH cutting at least a portion of the through-insulating structure 165 may be spaced apart from the side surface of the first stud 180a in the through-insulating structure 165.

The spacing distance between the first stud 180a and the dummy channel structures DCH may be different for each of the dummy channel structures DCH. For example, the distance between the dummy channel structures DCH disposed on the left side of the first stud 180a may be different from the distance between the dummy channel structures DCH disposed on the right side.

As described above, when the upper contact structures MC1 are disposed in the sub-regions, structural stability may be secured by regularly disposing the dummy channel structures DCH while cutting a portion of the upper contact structures MC1.

Accordingly, in the upper contact region R3, the dummy channel structures DCH are spaced apart from each other by a spacing distance Id that is smaller than the first distance I1, which is the spacing distance between the upper contact structures MC1, and smaller than the first width W1, which represents the maximum diameter of the upper surface of the through-insulating structure. This arrangement helps ensure structural stability in the upper contact region R3.

In this case, the dummy channel structures DCH, which cut into at least a portion of the upper contact structure MC1, may be offset from the center axis l1 of the upper contact structure MC1 to avoid direct contact with the first stud 180a.

The wordline contact structures MC2 may be arranged spaced apart from each other by a second distance I2, and may be disposed in a zigzag pattern in the extension region R2. The second distance I2 may be greater than the first distance I1. The contact plug 170 and the side insulating layer 160 surrounding the contact plug 170 may be included.

The contact plug 170 may include a conductive layer, may bury the central region of the contact hole, and may include a pillar shape extending in the Z direction from the upper surface coplanar with the upper surface of the upper insulating layer 194 to the lower surface in contact with the allocated gate electrode 130. The wordline contact structures MC2 may include a bent portion depending on their length. The fourth width W4 of the upper surface of the wordline contact structures MC2 may be greater than the width of the lower surface, creating an inclined side surface between the upper surface and the lower surface. The upper surface of the wordline contact structures MC2 may be coplanar with the upper surface of the through-insulating structure 165 of the upper contact structures MC1, and may be coplanar with the upper surface of the stack structure GS.

The contact plug 170 may further include a conductive layer and a contact barrier layer on the side surface and lower surface of the conductive layer. The fourth width W4 of the upper surface of the wordline contact structure MC2 may be almost the same as the width of the upper surface of the contact plug 170, but an example embodiment thereof is not limited thereto. The fourth width W4 of the wordline contact plug MC4 may be greater than or may be the same as the first width W1 of the upper contact structure MC1.

A side insulating layer 160 may be disposed between the stack structures GS penetrated by the contact plug 170 and the contact plug 170. The side insulating layer 160 may be disposed on the side surface of the contact plug 170, and the upper end may be positioned at the same level as the upper surface of the contact plug 170, and the lower end may be positioned at a level the same as or higher than a level of the lower surface of the contact plug 170. The lower end of the side insulating layer 160 may be disposed to expose an upper surface of the allocated gate electrode 130, and may be disposed to insulate the gate electrodes 130 of an upper portion of the allocated gate electrode 130.

The side insulating layer 160 may be disposed on the side surface of the wordline contact structures MC2, electrically insulating the wordline contact structures MC2 from the adjacent gate electrodes 130. Additionally, the side insulating layer 160 may be in physical and electrical contact with the contact region of the allocated gate electrode 130 through the lower surface of the exposed wordline contact structures MC2.

In the extension region R2, when one wordline contact structure MC2 is allocated to each of the memory gate electrodes 130M and the lower gate electrodes 130L, the wordline contact structures MC2 may have different lengths so as to be connected to the gate electrodes 130M and 130L of different levels.

In an example embodiment in FIGS. 2A, 2B, 3A, 3B, and 3C, the first to third stack structure GS1-GS3 is illustrated as including gate electrodes 130 of each of eight levels, and as eight gate electrodes 130U in an upper portion are upper gate electrodes 130U, 17 gate electrodes 130M and 130L may remain. Wordline contact structures MC2 of which lengths are adjusted differently so as to be in contact with the upper surfaces of the 17 gate electrodes 130M and 130L may be disposed in the extension region R2.

The arrangement of wordline contact structures MC2 may be arranged in various manners, and in an example embodiment, as illustrated in FIG. 1, the wordline contact structures MC2 may be arranged to be lowered in the Z-direction and the Y-direction in 1 column and may be in contact with each allocated gate electrode 130, and may be lowered in the Z-direction and the X-direction and may be in contact with each allocated gate electrode 130, but an example embodiment thereof is not limited thereto. For example, the wordline contact structures MC2 may be arranged in one row, and may be arranged symmetrically such that the length may increase toward the center. The wordline contact structures MC2 disposed in the last column may include dummy wordline contact structures MC2, and may function as the support structure SH without performing the function of selecting an actual wordline.

In FIG. 2A, wordline contact structures MC2 in contact with the 9th and 12th gate electrodes 130 are illustrated, but an example embodiment thereof is not limited thereto. The length of the wordline contact structures MC2 in the Z direction may indicate that the level of the upper surface is the same and the level of the lower surface is lowered.

The contact plug 170 of the upper contact structures MC1 and the wordline contact structures MC2 may include the same conductive material layer, for example, at least one of tungsten (W), copper (Cu), aluminum (Al), or an alloy thereof. For example, the conductive material layer may include tungsten (W). The contact barrier layer 171 may surround the conductive material layer and may include tungsten nitride (WN), tantalum nitride (TaN), titanium nitride (TiN), or a combination thereof.

The upper insulating layer 194 may be disposed to cover the stack structure GS, and may be disposed to cover the channel structures CH, the dummy channel structures DCH, the through-insulating structure 165, and the wordline contact structures MC2. The upper insulating layer 194 may be formed of an insulating material, and may include at least one of silicon oxide, silicon nitride, or silicon oxynitride, for example.

The upper insulating layer 194 may be disposed to have a predetermined thickness, and may be penetrated by the first to third studs 180a, 180b, and 180c. The upper insulating layer 194 may include at least one of SiO, SiN, SiCN, SiOC, SiON, or SiOCN.

The second and third studs 180b and 180c, along with the cell interconnection lines 185, may be disposed. The second studs 180b may be disposed in the extension region R2, penetrating the upper insulating layer 194, and may be in contact with the upper surface of the wordline contact structures MC2. The third studs 180c may be disposed in the memory region R1, penetrating the upper insulating layer 194, connected to the channel pad 149 of the channel structures CH, and electrically connected to the channel layers 140.

The lengths and the shapes of the second and third studs 180b and 180c may be the same, and the second and third studs 180b and 180c may have an inclined side surface as a width decreases from the upper surface to the lower surface. The upper surfaces of the first studs 180a and the second and third studs 180b and 180c may be positioned at the same level, and the lower surfaces of the second and third studs 180b and 180c may be positioned at the same level, and the lower surface Sb of the first studs 180a may be positioned at a lower level. The upper surface width W2 of the first studs 180a may be substantially the same as the upper surface width W3 of the second and third studs 180b and 180c, but an example embodiment thereof is not limited thereto.

The first and second studs 180a and 180b may be electrically connected to the respective gate electrodes 130 through contact plugs MC1 and MC2 connected to the lower surfaces, respectively. The studs 180a, 180b, and 180c may have a plug-like shape, and the cell interconnection lines 185 may have a line-like shape, but an example embodiment thereof is not limited thereto. The first to third studs 180a, 180b, and 180c may include the same conductive material layer 183, and may include a metal. For example, the conductive material layer 183 may include tungsten (W), copper (Cu), aluminum (Al), or the like, and may further include a contact barrier layer 184 similar to the first studs 180a.

The cell interconnection lines 185 may include a metal, for example, tungsten (W), copper (Cu), aluminum (Al), or the like. An insulating layer covering the cell interconnection lines 185 may be further disposed. The insulating layer may be formed of an insulating material, for example, at least one of SiO, SiN, SiCN, SiOC, SiON, or SiOCN.

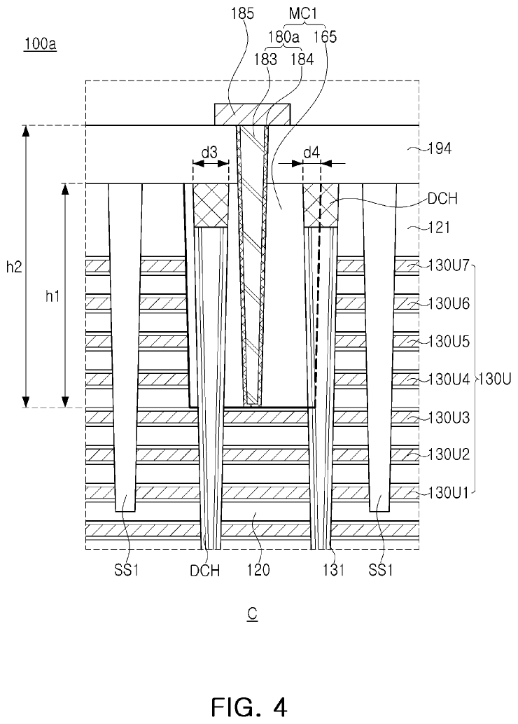

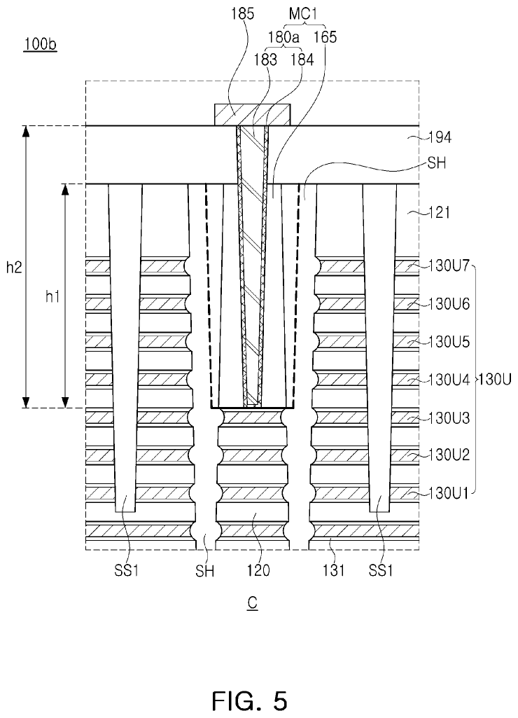

FIG. 4 and FIG. 5 are enlarged cross-sectional diagrams illustrating a semiconductor device according to example embodiments.

The semiconductor device 100a in FIG. 4 may be the same as the semiconductor device 100 in FIGS. 1, 2A, 2B, 3A, 3B and 3C, other than the shapes of the upper contact structure MC1 and the dummy channel structure DCH.

At least one of the dummy channel structures DCH disposed around the upper contact structure MC1 may be disposed to penetrate the through-insulating structure 165 of the upper contact structure MC1.

The dummy channel structures DCH disposed on one of the left side or the right side of the upper contact structure MC1 may be disposed to penetrate the through-insulating structure 165, such that the entirety of the dummy channel structures DCH may be disposed in the through-insulating structure 165.

The dummy channel structures DCH disposed on the other side of the left side or the right side of the upper contact structure MC1 may be disposed to penetrate only a portion of the through-insulating structure 165, such that only a portion of the dummy channel structures DCH may cut the upper contact structure MC1.

Accordingly, the other portion of the dummy channel structures DCH on the other side may penetrate the stack structure GS. The protruding length d3 of the dummy channel structures DCH on one side of the upper contact structure MC1 and the through-insulating structure 165 may be greater than the protruding length d4 of the dummy channel structures DCH on the other side of the upper contact structure MC1 and the through-insulating structure 165.

However, the dummy channel structures DCH on one side may also be physically spaced apart from the first stud 180a therein.

The semiconductor device 100b in FIG. 5 may be the same as the semiconductor device 100 in FIGS. 1, 2A, 2B, 3A, 3B and 3C other than the configuration in which the support structures SH are disposed in the upper contact region R3, rather than the dummy channel structures DCH.

The support structures SH may include the support structures SH penetrating the stack structure GS between the support structures SH and the upper contact structures MC1, disposed in close proximity to the upper contact structures MC1 similar to the arrangement of the dummy channel structures DCH. The arrangement of the support structures SH may be the same as the arrangement of the dummy channel structures DCH, as illustrated in FIG. 1.

The support structures SH may be the same as the support structures SH of the extension region R2, and may have a width smaller than a width of the support structures SH in the extension region R2, but an example embodiment thereof is not limited thereto.

The support structures SH disposed by cutting a portion of the upper contact structures MC1 may be disposed such that a portion may penetrate the upper contact structures MC1 and the other portion may penetrate the stack structure GS.

A portion of the upper contact structure MC1, specifically the portion in contact with the through-insulating structure 165, may extend flatly along the side surface of the support structures SH. The portion of the side surface, which is in contact with the stack structure GS, may have a shape in which a convex projection is continuously disposed. The convex projection may protrude toward the gate electrodes 130.

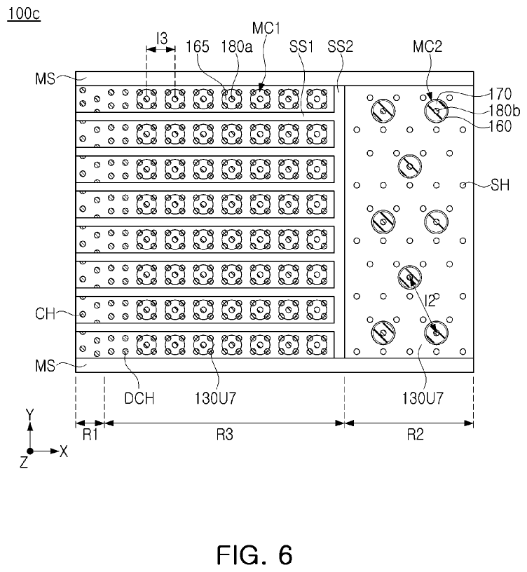

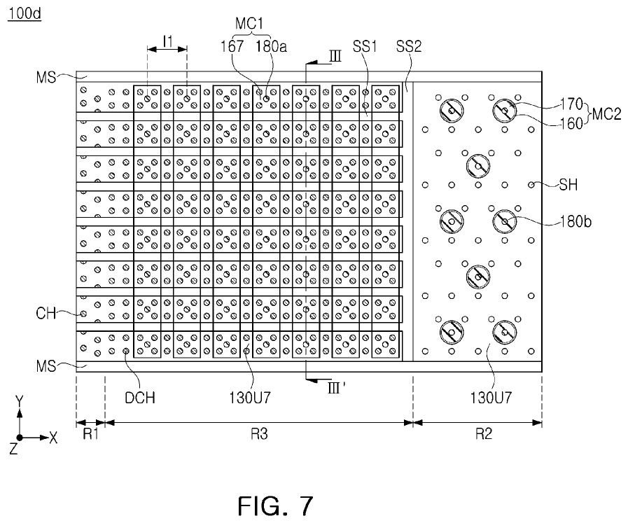

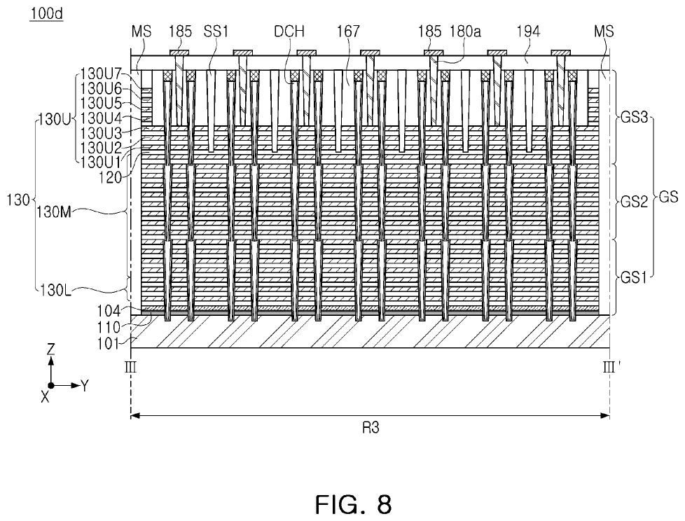

FIG. 6 to FIG. 7 are diagrams illustrating a semiconductor device according to example embodiments, viewed from above. FIG. 8 is a cross-sectional diagram illustrating the semiconductor device illustrated in FIG. 7, taken along line III-III′ in FIG. 7.

The semiconductor device 100c in FIG. 6 may be the same as the semiconductor device 100 in FIGS. 1, 2A, 2B, 3A, 3B and 3C other than the arrangement in the upper contact region.

The upper contact structures MC1 in FIG. 6 may be arranged in a row in the sub-regions and may be arranged to have a third distance I3 from the neighboring upper contact structures MC1. In this case, the third distance I3 may represents a pitch, which is the distance between center axes l1 of the upper contact structures MC1, and the third distance I3 may be smaller than the first distance I1 in FIG. 1.

Accordingly, the upper contact structures MC1 may be disposed in close proximity to each other, with at least a portion of the stack structure GS disposed between the upper contact structures MC1. As a result, the side surfaces of both upper contact structures MC1 may remain spaced apart, without coming into direct contact with one another.

Dummy channel structures DCH may be disposed while cutting a portion of the upper contact structures MC1 around each upper contact structure MC1, and the dummy channel structures DCH may be arranged by cutting a portion of the upper channel structures MC1. That is, as in FIG. 1, the dummy channel structures DCH disposed in a spacing between the upper contact structures MC1 and penetrating only the stack structure GS may not be disposed.

The semiconductor device 100d in FIGS. 7 and 8 may be the same as the semiconductor device 100 in FIGS. 1, 2A, 2B, 3A, 3B and 3C, other than the configuration in which the through-insulating structures 165 are disposed as bar type extending in the Y-direction to be interconnected for a plurality of sub-regions.

The semiconductor device 100d in FIGS. 7 and 8 may include a shared through-insulating structure 167 penetrating the sub-regions between the adjacent isolation regions MS in the Y direction in a block and extending in the Y direction in a bar type in a plan view.

The shared through-insulating structure 167 may extend in the Y direction to simultaneously surround the first studs 180a disposed in one column in each sub-region.

Accordingly, the shared through-insulating structure 167 may simultaneously penetrate the sub-regions.

The shared through-insulating structure 167 may surround the first studs 180a disposed in the same column in a plurality of sub-regions, and the entirety of the first studs 180a disposed in the shared through-insulating structure 167 may be in contact with the same upper gate electrode 130U.

In FIG. 7, it is illustrated that eight sub-regions are provided and seven first studs 180a are arranged in a row in each sub-region, but the number of the elements may vary.

The shared through-insulating structure 167 may be a structure stacked with an insulating material, such that eight first studs 180a in the shared through-insulating structure 167 may be in contact with the same upper gate electrode 130U, and the first studs 180a of each sub-region in the shared through-insulating structure 167 may be in contact with the allocated upper gate electrode 130U.

In this case, the first insulating regions SS1 may be disposed to penetrate the shared through-insulating structure 167 and to penetrate the upper gate electrodes 130U between the first studs 180a.

Accordingly, the lower end of the first insulating regions SS1 may be disposed at a level lower than a level of the lower surface of the shared through-insulating structure 167.

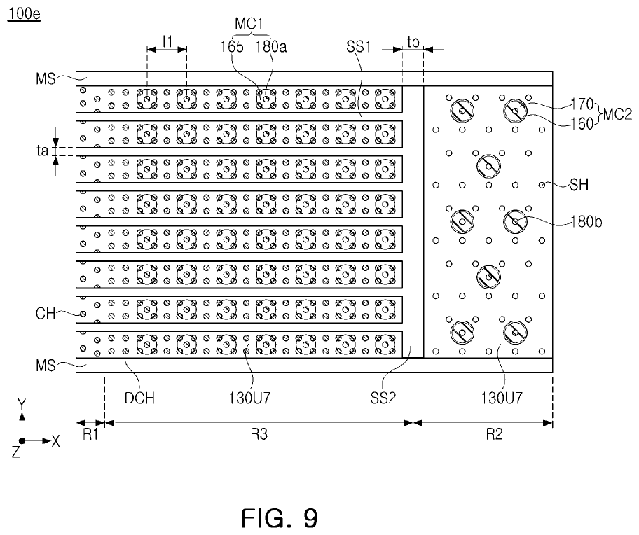

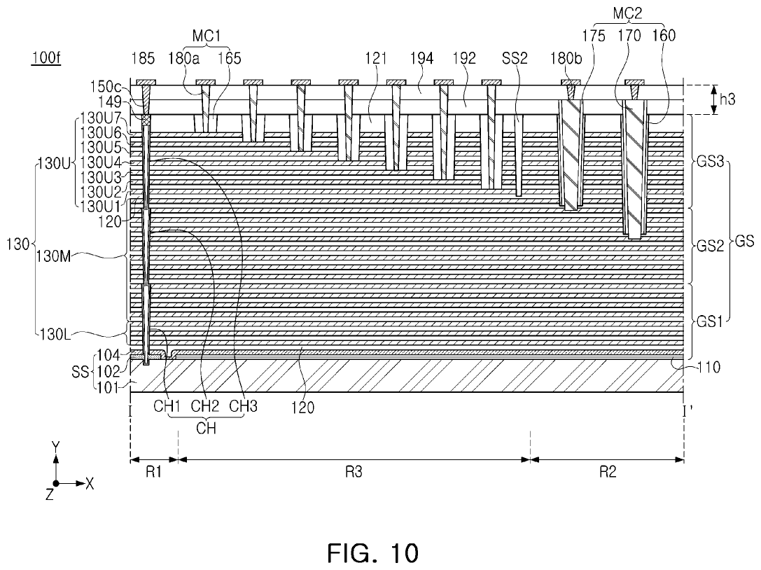

FIG. 9 is a diagram illustrating a semiconductor device according to example embodiments, and FIG. 10 is a cross-sectional diagram of a semiconductor device according to example embodiments.

The semiconductor device 100e in FIG. 9 may be the same as the semiconductor device 100 in FIGS. 1, 2A, 2B, 3A, 3B and 3C, other than the configuration in which the width tb of the second insulating region SS2 is greater than the width ta of the first insulating region SS1.

The first insulating region SS1 in FIG. 9 may have the second insulating width tb, the second insulating region SS2 may have the first insulating width ta, and the second insulating width tb may be greater than the first insulating width ta.

The second insulating width tb may have a size substantially similar to the first width W1, which is the width of the upper surface of the upper contact structure MC1, but an example embodiment thereof is not limited thereto.

The second insulating region SS2 having a relatively large width may be formed concurrently with the through-insulating structures 165 of the upper contact structures MC1. Both structures may be patterned using the same etching process, such that the upper portion of the second insulating region SS2 has a width similar to that of the through-insulating structures 165.

The dummy channel structures DCH penetrating the second insulating region SS2 may be further disposed by in the second insulating region SS2 having a greater width.

The dummy channel structures DCH in the second insulating region SS2 may be disposed in the second insulating region SS2 as illustrated in FIG. 9, or alternatively, the dummy channel structures DCH may be disposed by cutting a portion of the second insulating region SS2.

The dummy channel structures DCH are illustrated as being arranged in one row in the second insulating region SS2, but an example embodiment thereof is not limited thereto, and the dummy channel structures DCH may be arranged in various arrangements.

The semiconductor device 100f in FIG. 10 may have a structure in which the upper insulating layer is stacked in order on the stack structure GS, the first upper insulating layer 192 and the second upper insulating layer 194.

The first and second upper insulating layers 192, 194 may include the same insulating material, but an example embodiment thereof is not limited thereto.

Referring to FIG. 10, the through-insulating structures 165 of the upper contact structure MC1 of the semiconductor device 100f may have the same structure as FIG. 1, FIG. 2A, FIG. 2B, FIG. 3A, FIG. 3B and FIG. 3C, and the first studs 180a may extend from the second upper insulating layer 194 by penetrating the first upper insulating layer 192 and the through-insulating structure 165. Accordingly, the length in the Z direction of the first studs 180a may be longer, and the third length h3 from the upper surface of the through-insulating structure 165 to the upper surface Sa of the first studs 180a may be longer.

In the wordline contact structures MC2, the upper surface of the contact plugs 170 may be disposed at a level higher than the upper surface of the through-insulating structures 165, and may be coplanar with the upper surface of the first upper insulating layer 192.

The second side insulating layer 175 may be further disposed between the first side insulating layer 160 and the contact plug 170, between the contact plug 170 and the gate electrodes 130. The second side insulating layer 175 may be in direct contact with the side surface of the contact plug 170, and may have upper end at the same level as the upper surface of the contact plug 170, and may have a lower end substantially aligned with the lower end of the first side insulating layer 160. Accordingly, the upper end of the second side insulating layer 175 may be positioned at a level higher than a level of the upper end of the first side insulating layer 160, and may extend to penetrate the first upper insulating layer 192. As a result, the upper surface of the contact plug 170 and the upper end of the second side insulating layer 175 may be exposed on the first upper insulating layer 192, whereas the upper end of the first side insulating layer 160 may remain unexposed. The first upper insulating layer 192, the upper surface of the contact plug 170, and the upper end of the second side insulating layer 175 may be substantially coplanar with each other, but an example embodiment thereof is not limited thereto.

The second side insulating layer 175 may be disposed with a substantially uniform thickness along its side surface, extending from the upper end to the lower end. The thickness of the second side insulating layer 175 may be equal to or greater than the thickness of the first side insulating layer 160, or may be less than the thickness of the interlayer insulating layers 120.

The first side insulating layers 160 may include an insulating material, for example, silicon oxide, silicon nitride, or silicon oxynitride. The second side insulating layer 170 may include silicon oxide, undoped polysilicon, or silicon nitride.

The second studs 180b disposed on the wordline contact structure MC2 may penetrate the second upper insulating layer 194, and may be disposed such that the upper surface may be coplanar with the first stud 180a and the lower surface may be in contact with the upper surface of the contact plug 170.

Referring to FIG. 11, the semiconductor device 100g may include a first semiconductor structure S1 and a second semiconductor structure S2 below the first semiconductor structure S1. The first semiconductor structure S1 may include a memory cell region, and the second semiconductor structure S2 may include a peripheral circuit region. In some example embodiments, the second semiconductor structure S2 may be disposed on the first semiconductor structure S1.

As for the first semiconductor structure S1, the description described with reference to FIGS. 1, 2A, 2B, 3A, 3B and 3C may be applied.

The second semiconductor structure S2 may include a substrate 201, source/drain regions 205 and device isolation layers 210 in the substrate 201, circuit devices 220 disposed on the substrate 201, a peripheral region insulating layer 290, circuit contact plugs 270, and circuit interconnection lines 280.

The substrate 201 may have a lower surface extending in the X-direction and the Y-direction. The substrate 201 may have an active region defined by device isolation layers 210. Source/drain regions 205 including impurities may be disposed on a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit devices 220 may include a planar transistor. Each of the circuit devices 220 may include a circuit gate dielectric layer 222, a spacer layer 224, and a circuit gate electrode 225. The source/drain regions 205 may be disposed as a source/drain region in the substrate 201 on both sides of the circuit gate electrode 225.

The peripheral region insulating layer 290 may be disposed to cover the circuit devices 220 on the lower surface of the substrate 201. The peripheral region insulating layer 290 may include a plurality of insulating layers formed in different processes. The peripheral region insulating layer 290 may be formed of an insulating material.

Circuit contact plugs 270 and circuit interconnection lines 280 may be included in a circuit interconnection structure electrically connected to the circuit devices 220 and the source/drain regions 205. The circuit contact plugs 270 may have a cylindrical shape, and the circuit interconnection lines 280 may have a line shape. An electrical signal may be applied to the circuit device 220 by the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270 and may be disposed in a plurality of layers. The circuit contact plugs 270 and the circuit interconnection lines 280 may include conductive materials, for example, tungsten (W), copper (Cu), aluminum (Al), or the like, and each element may further include a diffusion barrier. In example embodiments, the number of layers of the circuit contact plugs 270 and the circuit interconnection lines 280 may vary.

The semiconductor device 100h in FIG. 12 may include the semiconductor device 100 in FIGS. 1, 2A, 2B, 3A, 3B and 3C as a first semiconductor structure S1, and a second semiconductor structure S2 may be disposed as a peripheral circuit structure below the first semiconductor structure S1. The first semiconductor structure S1 may be stacked in the Z-direction perpendicular to the second semiconductor structure S2. Specifically, the first semiconductor structure S1 may be disposed in an upper portion with respect to the second semiconductor structure S2 in the Z-direction. In example embodiments, conversely, the second semiconductor structure S2 may be disposed on an upper portion of the first semiconductor structure S1.

The first semiconductor structure S1 may further include a bonding structure. Specifically, first bonding vias 195, first bonding metal layers 198, and first bonding insulating layer 199 may be included in the first bonding structure of the first semiconductor structure S1. The first bonding vias 195 may be disposed on cell interconnection lines 185, and the first bonding metal layers 198 may be connected to the first bonding vias 195. The first bonding metal layers 198 may have an upper surface exposed to the upper surface of the first semiconductor structure S1. The first bonding metal layers 198 may be bonded and connected to second bonding metal layers 298 of the second semiconductor structure S2. The first bonding vias 195 and the first bonding metal layers 198 may include a conductive material, for example, copper (Cu). The first bonding insulating layer 199 may form dielectric-dielectric bonding with the second bonding insulating layer 299 of the second semiconductor structure S2.

The second semiconductor structure S2 may be similar to the second semiconductor structure S2 in FIG. 11 and may include second bonding vias 295 and second bonding metal layers 298 on the peripheral region insulating layer 290.

The peripheral region insulating layer 290 may be disposed to cover the circuit devices 220 on the lower surface of the substrate 201. The peripheral region insulating layer 290 may include a plurality of insulating layers formed in different processes. The peripheral region insulating layer 290 may be formed of an insulating material. A portion of the peripheral region insulating layer 290 may function as a second bonding insulating layer 299.

Circuit contact plugs 270 and circuit interconnection lines 280 may be included in a circuit interconnection structure electrically connected to the circuit devices 220 and the source/drain regions 205. The circuit contact plugs 270 may have a cylindrical shape, and the circuit interconnection lines 280 may have a line shape. An electrical signal may be delivered to the circuit device 220 through the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270 and may be disposed in multiple layers. The circuit contact plugs 270 and the circuit interconnection lines 280 may include a conductive material, for example, tungsten (W), copper (Cu), aluminum (Al), or the like, and each of the elements may further include a diffusion barrier. In example embodiments, the number of layers of the circuit contact plugs 270 and the circuit interconnection lines 280 may vary.

The second bonding vias 295 and the second bonding metal layers 298, and the second bonding insulating layer 299 may be included in the second bonding structure, and may be disposed below a portion of the lowermost portion of the circuit interconnection lines 280. The second bonding vias 295 may have a cylindrical shape, and the second bonding metal layers 298 may have a pad shape having a circular shape on plane or a relatively short line shape. The lower surfaces of the second bonding metal layers 298 may be exposed to the lower surface of the second substrate structure S2. The second bonding vias 295 and the second bonding metal layers 298 may provide electrical connection paths with the first semiconductor structure S1. In example embodiments, a portion of the second bonding metal layers 298 may be formed solely for bonding purposes without being connected to the circuit interconnection lines 280. The second bonding vias 295 and the second bonding metal layers 298 may include a conductive material, for example, copper (Cu).

The second bonding insulating layer 299 may be defined with a predetermined thickness from the lower surface of the peripheral region insulating layer 290, but may also be implemented as an insulating layer on the lower surface of the peripheral region insulating layer 290. The second bonding insulating layer 299 may be provided for dielectric-dielectric bonding with the first bonding insulating layer 199 of the first semiconductor structure S1. The second bonding insulating layer 299 may also function as a diffusion barrier for the second bonding metal layers 298, and may include, for example, at least one of SiO, SiN, SiCN, SiOC, SiON, or SiOCN.

The first and second semiconductor structures S1 and S2 may be bonded to each other by bonding between the first bonding metal layers 198 and the second bonding metal layers 298 and by bonding between the first bonding insulating layer 199 and the second bonding insulating layer 299. The bonding between the first bonding metal layers 198 and the second bonding metal layers 298 may be, for example, copper (Cu)-copper (Cu) bonding, and the bonding between the first bonding insulating layer 199 and the second bonding insulating layer 299 may be, for example, dielectric-dielectric bonding, such as SiCN-SiCN bonding. The first and second semiconductor structures S1 and S2 may be bonded to each other by hybrid bonding including copper (Cu)-copper (Cu) bonding and dielectric-dielectric bonding.

As illustrated in FIG. 12, the first and second semiconductor structures S1 and S2 may be packaged in a form in which the first semiconductor structure S1 is positioned on the top, or alternatively, the first and second semiconductor structures S1 and S2 may be disposed upside down, the second semiconductor structure S2 being positioned on the top.

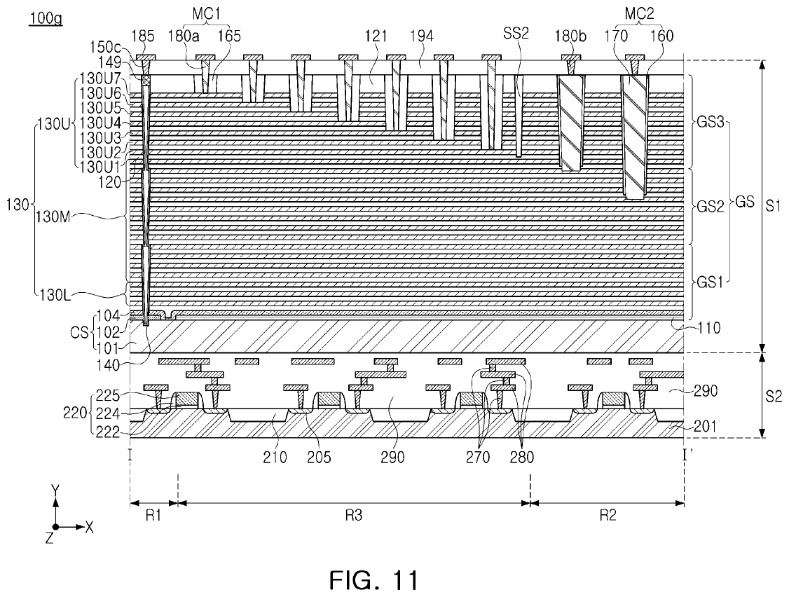

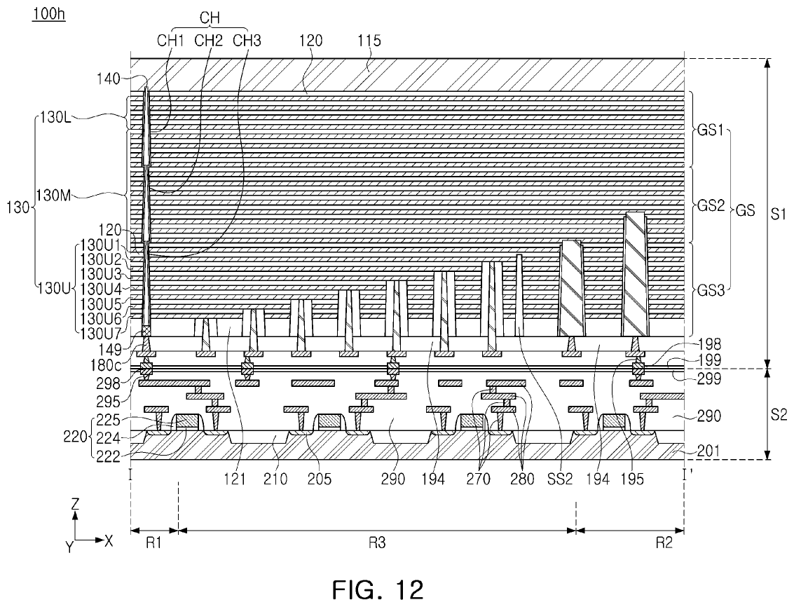

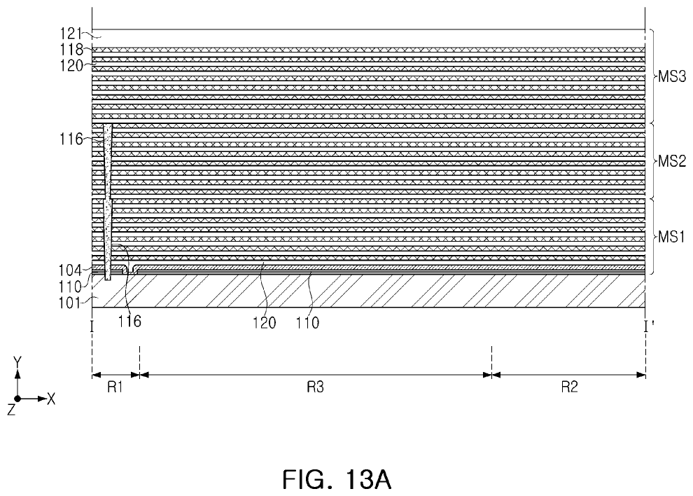

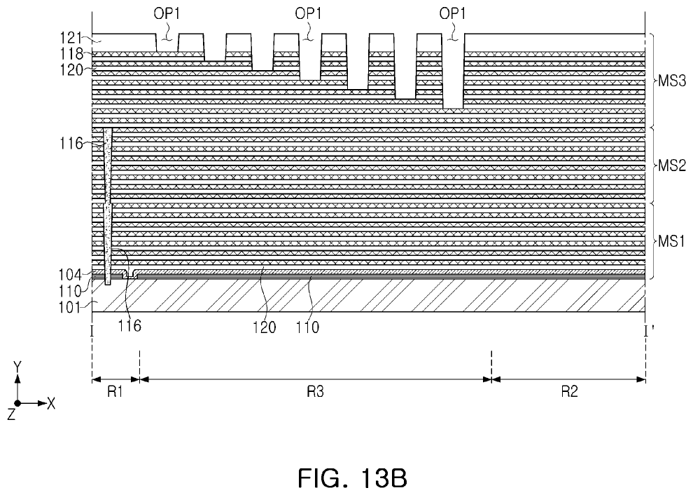

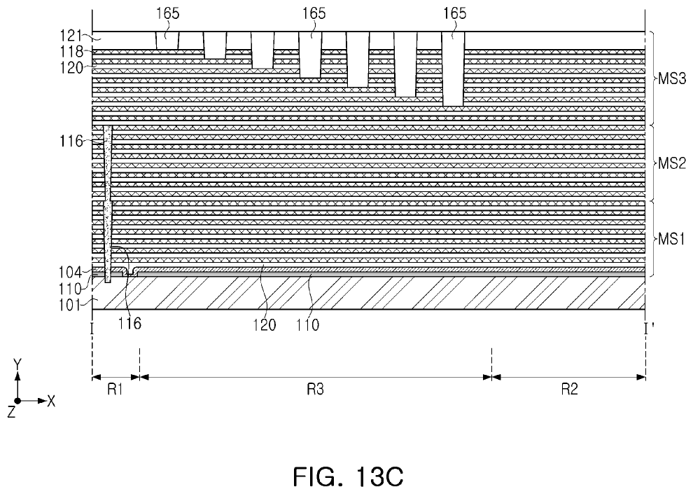

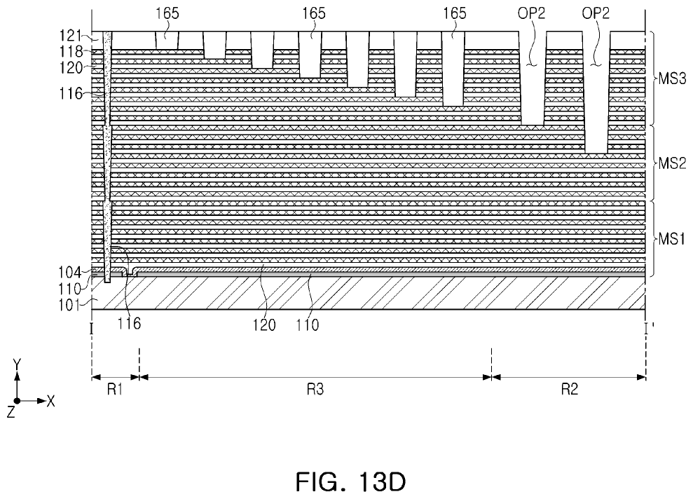

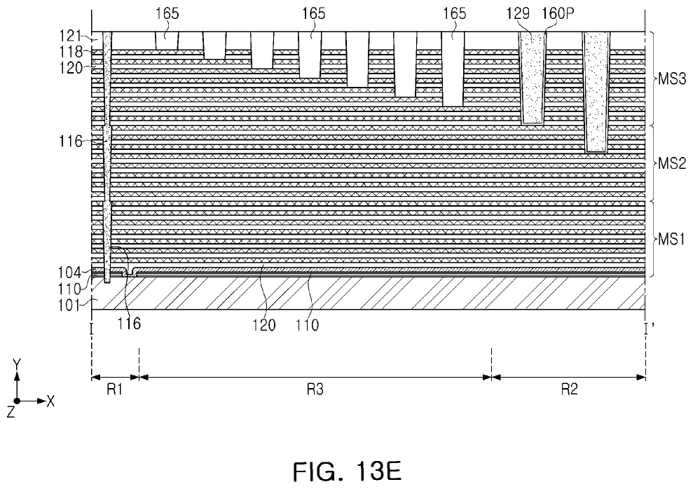

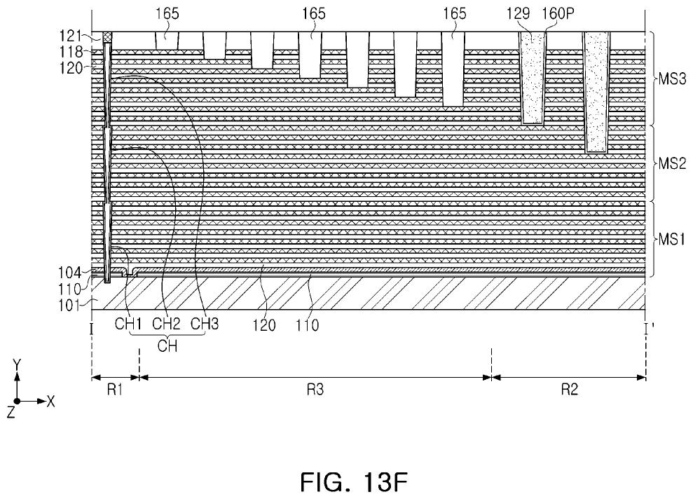

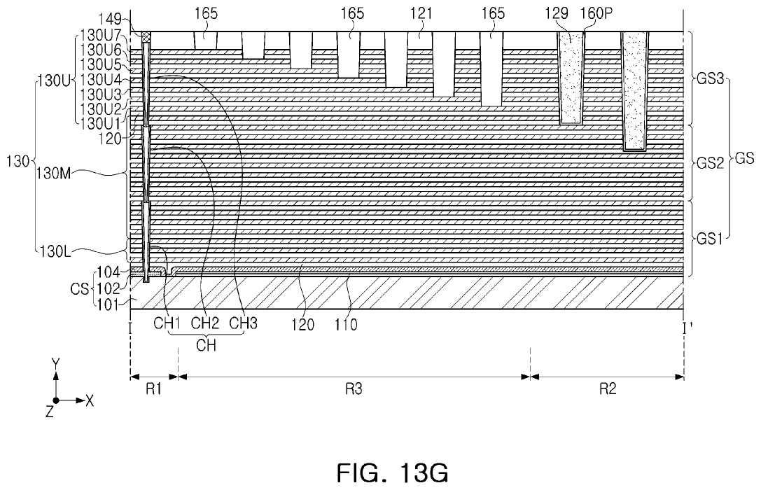

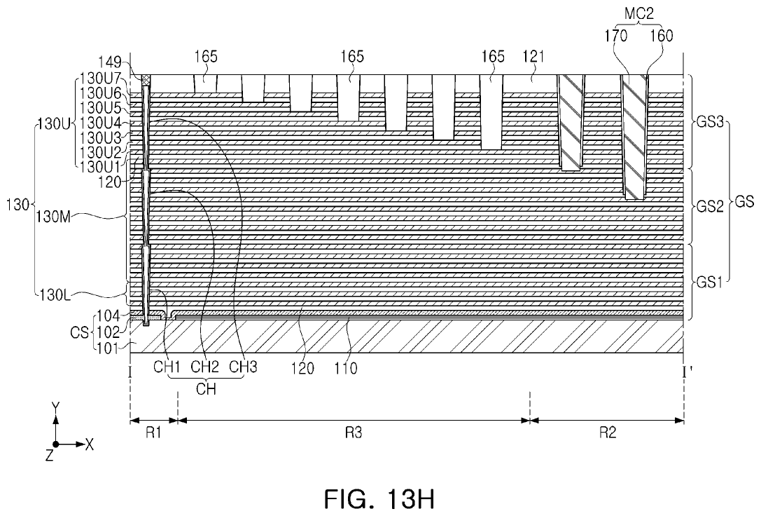

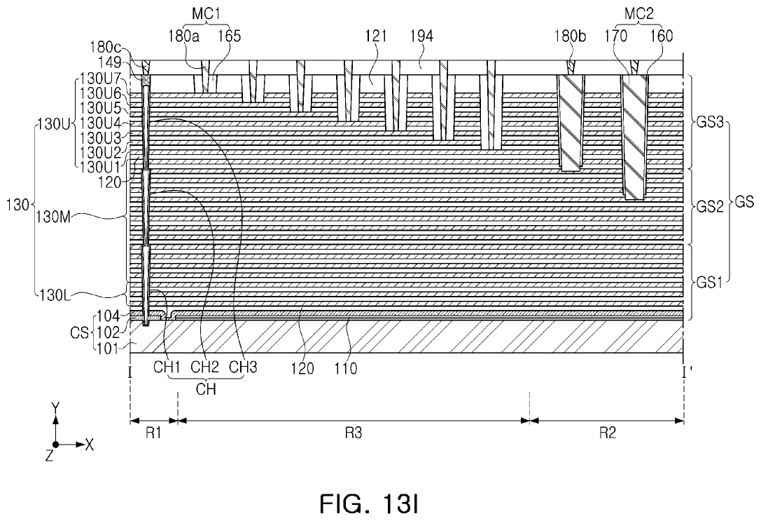

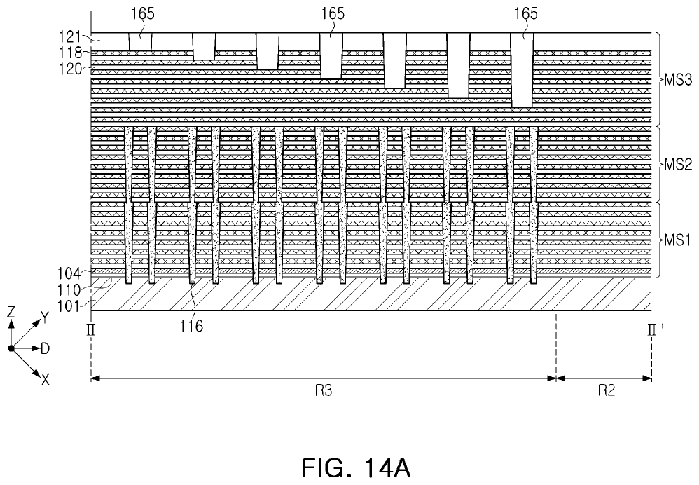

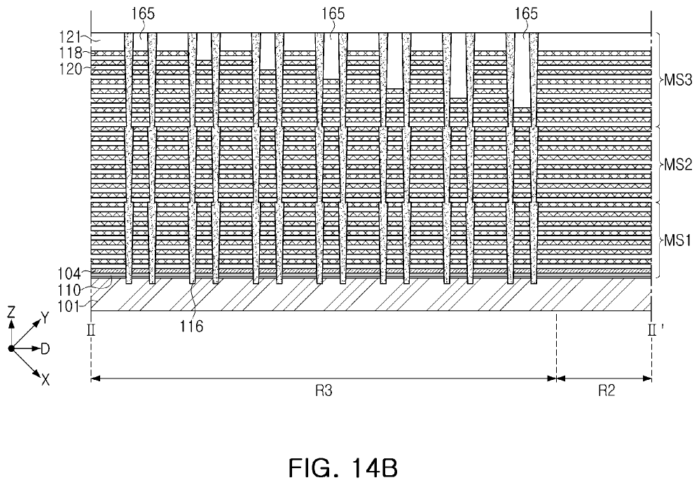

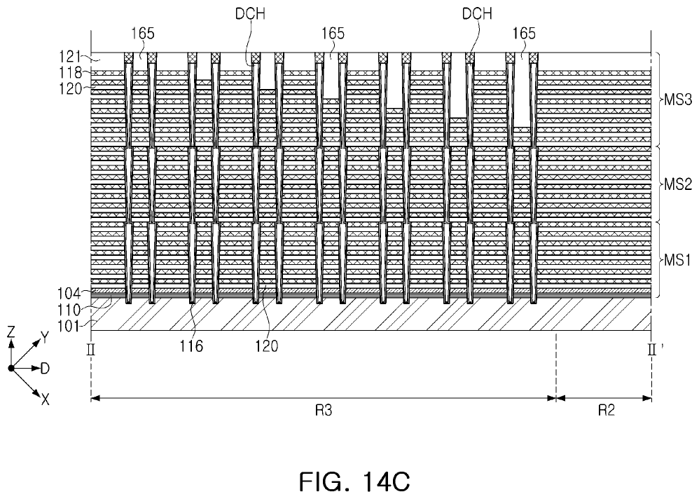

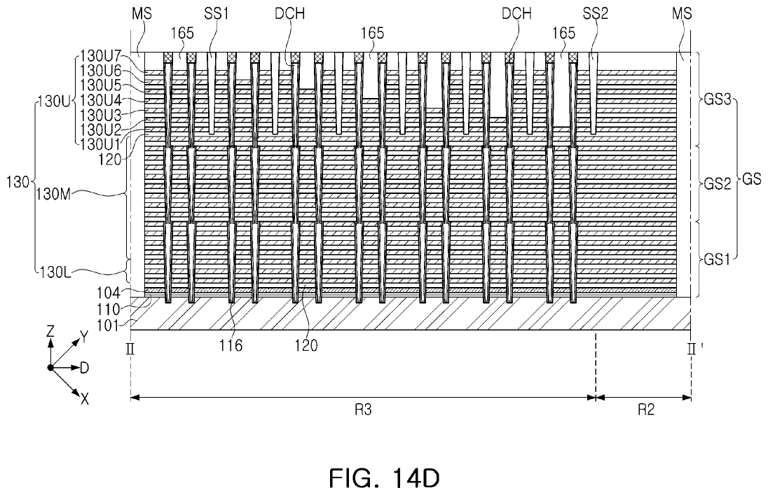

FIGS. 13A to 13I and 14A to 14D are cross-sectional diagrams illustrating a method of manufacturing a semiconductor device according to example embodiments.

FIGS. 13A to 13I and 14A to 14D are cross-sectional diagrams illustrating a method of manufacturing a semiconductor device in example embodiments, illustrating a cross-sectional surface corresponding to FIG. 2A, and FIGS. 14A to 14D illustrate a cross-sectional surface corresponding to FIG. 2B.

Referring to FIG. 13A, sacrificial insulating layers 118 and interlayer insulating layers 120 are alternately stacked on a substrate 101, and mold structures MS1-MS3 may be formed by forming up to an uppermost interlayer insulating layer 121. Vertical sacrificial structures 116 penetrating the mold structures MS1-MS3 may be formed.

The substrate 101 may be a semiconductor substrate such as a silicon (Si) wafer. First, a first mold structure MS1 of the mold structure MS1-MS3 may be formed and high aspect ratio contact (HARC) etching to penetrate the structure may be performed, and a portion of the vertical sacrificial structures 116 may be formed, and a second mold structure MS2 may be formed, HARC etching to penetrate the structure may be performed, and a portion of the vertical sacrificial structures 116 may be formed. In the same manner, a third mold structure MS3 may be formed.

The sacrificial insulating layers 118 may be replaced with gate electrodes 130 (see FIG. 2A) through a subsequent process. The sacrificial insulating layers 118 may be formed of a different material from a material of the interlayer insulating layers 120, and may be formed of a material etched with etching selectivity under specific etching conditions with respect to the interlayer insulating layers 120. For example, the interlayer insulating layer 120 may be formed of at least one of silicon oxide or silicon nitride, and the sacrificial insulating layers 118 may be formed of a material other than the interlayer insulating layer 120 selected from among silicon, silicon oxide, silicon carbide, and silicon nitride. In example embodiments, the thicknesses of the interlayer insulating layers 120 may not be the same, and the uppermost interlayer insulating layer 121 may have a thickness greater than a thickness of the other interlayer insulating layers 120. The thicknesses of the interlayer insulating layers 120 and sacrificial insulating layers 118 and the number of films included in the layers may vary from the illustrated example.

The vertical sacrificial structures 116 may be formed at positions corresponding to the channel structures CH, the dummy channel structures DCH, and the support structures SH in FIG. 2A. The vertical sacrificial structures 116 may be formed, for example, to have the same size as the channel structures CH, the dummy channel structures DCH, and the support structures SH. The vertical sacrificial structures 116 may include, for example, carbon (C), but an example embodiment thereof is not limited thereto.

Referring to FIG. 13B, a mask layer may be formed on the uppermost interlayer insulating layer 121, and accordingly, upper contact holes OP1 may be formed to form upper contact structures MC1 in the upper contact region R3.

Specifically, upper contact holes OP1 may be formed to reach the allocated upper gate electrode 130U (corresponding sacrificial insulating layer 118) of each upper contact structure MC1 by performing etching multiple times. In the forming the upper contact holes OP1, the number of performing etching and the etching order may be applied differently depending on the level of the allocated gate electrode 130.

For example, when the total number of layers of the entire upper gate electrodes 130U is m, when converted to binary, contact etching may be performed as many times as the number of digits of the binary number. Contact etching may be performed at different depths depending on the number of digits of the converted binary number. For example, contact etching corresponding to the first digit may include etching the sacrificial insulating layer 118 and the interlayer insulating layer 120 corresponding to one (2⁰) gate electrode, and contact etching corresponding to the second digit may include etching the sacrificial insulating layers 118 and the interlayer insulating layers 120 corresponding to two (2¹) gate electrodes simultaneously. Contact etching corresponding to the third digit may include etching the sacrificial insulating layers 118 and the interlayer insulating layers 120 corresponding to four (2²) gate electrodes.

By converting the number of layers of each allocated upper gate electrode 130U into a binary number, and applying contact etching corresponding to the number of digits having 1 in the converted binary number, upper contact holes OP1 may be formed with different depths.

Accordingly, by applying contact etching corresponding to the number of digits of the binary number differently to the upper contact hole OP1, etching may be performed only as many times as the number of digits of the binary number, and the upper contact holes OP1 with different depths may be formed such that the upper gate electrodes 130U of different levels may be opened, respectively.

As illustrated in FIGS. 13C and 14A, through-insulating structures 165 may be formed in each upper contact hole OP1.

The through-insulating structure 165 may include a material different from the sacrificial insulating layer 118 and may include an insulating material. Accordingly, the through-insulating structure 165 may include silicon oxide, silicon oxycarbide, or the like.

The through-insulating structure 165 may be formed by over-depositing an insulating material to cover the upper surface of the mold structure MS1-MS3 and flattening to expose the upper surface of the mold structure MS1-MS3, but an example embodiment thereof is not limited thereto.

Accordingly, a portion of the vertical sacrificial structures 116 for the dummy channel structures DCH may be arranged below the through-insulating structure 165.

Referring to FIGS. 13D and 14B, vertical sacrificial structures 116 penetrating the third mold structure MS3 may be formed, and contact holes OP2 may be formed in the extension region R2.

The vertical sacrificial structures 116 penetrating the third mold structures MS3 may be formed to extend from the vertical sacrificial structures 116 penetrating the second mold structure MS2, and may be formed by burying carbon after HARC etching.

The vertical sacrificial structures 116 may be formed by cutting at least a portion of the through-insulating structures 165 in the upper contact region R3, and accordingly, the state in which a portion of the through-insulating region R3 is partially removed by the vertical sacrificial structures 116 may be maintained.

In the extension region R2, a mask layer for wordline contact structures MC2 may be formed, and accordingly, contact holes OP2 may be formed to form upper contact structures MC2 in the extension region R2.

Specifically, the contact holes OP2 may be formed to reach the allocated gate electrode (corresponding sacrificial insulating layer 118) of each upper contact structure MC2 by performing etching multiple times. In the forming the contact holes OP2, the number of etchings and the order of etchings may be applied differently depending on the level of the allocated gate electrode 130.

For example, when the total number of layers of the entire gate electrodes 130 is n, when converted to binary, contact etching may be performed as many as the number of binary digits. Contact etching may be performed at different depths depending on the number of binary digits converted. The number of contact etching digits may be configured more, and the method may be the same as the method of forming the upper contact hole OP1.

By converting the number of layers of each allocated gate electrode 130 into a binary number, and applying contact etching of the digit having 1 in the converted binary number, contact holes OP2 may be formed with different depths.

Accordingly, by performing contact etching a number of times corresponding to the number of binary digits and varying this based on the contact hole OP2, etching may be carried out only as many times as the number of binary digits, and contact holes OP2 of different depths which may open gate electrodes 130 of different levels may be formed.

In this case, as the depth of the contact holes OP2 formed in the extension region R2 is greater than the depth of the upper contact holes OP1 formed in the upper contact region R3, the diameter W4 of the contact hole OP2 may be greater than the diameter W1 of the upper contact hole OP1.

Referring to FIG. 13E, preliminary contact insulating layers 160P and contact sacrificial layers 129 may be formed in the contact hole OP2.

The preliminary contact insulating layers 160P may be conformally formed to cover sidewalls and bottom surface of each of the contact holes OP2. For example, the preliminary contact insulating layers 160P may be formed using a chemical vapor deposition (CVD) process.

The contact sacrificial layers 129 may be formed to fill each of the contact holes OP2 on the preliminary contact insulating layers 160P. The contact sacrificial layers 129 may include a material different from a material of the preliminary contact insulating layers 160P, for example, carbon (C). The upper ends of the contact sacrificial layers 129 and the preliminary contact insulating layers 160P may be coplanar with the uppermost interlayer insulating layer 121.

Referring to FIGS. 13F and 14C, a portion of the vertical sacrificial structures 116 may be removed and channel structures CH and dummy channel structures DCH may be formed.

A mask layer may be formed to expose only the region corresponding to the channel structures CH in the memory region R1 and the region corresponding to the dummy channel structures DCH in the upper contact region R3. Then, by removing the exposed vertical sacrificial structures 116, channel holes may be formed. At least a portion of a channel dielectric layer 145, a channel layer 140, a channel buried insulating layer 147, and a channel pad 149 may be sequentially deposited inside the channel holes, thereby forming the channel structures CH and the dummy channel structures DCH.

The channel dielectric layer 145 may be formed to have a uniform thickness using an ALD or CVD process. In this process, the channel dielectric layer 145 may be formed entirely or partially, and a portion thereof extending perpendicularly to the substrate 101 along the channel structures CH may be formed in this process. The channel layer 140 may be formed on the channel dielectric layer 145 in the channel holes. A channel buried insulating layer 147 may be formed to fill the channel holes and may be an insulating material. The channel pad 149 may be formed of a conductive material, for example, polycrystalline silicon.

Accordingly, dummy channel structures DCH cutting through-insulating structures 165 as in FIG. 14C may be formed, and dummy channel structures DCH disposed between the through-insulating structures 165 in FIG. 1 may also be formed.

A portion of vertical sacrificial structures 116 may be removed and support structures SH may be formed.

A mask layer exposing a region corresponding to support structures SH in the extension region R2 may be formed, and the exposed vertical sacrificial structures 116 may be removed, forming dummy holes. A process of expanding the dummy holes may be performed by partially removing the mold structure MS around the dummy holes. The expanded dummy holes may be filled with an insulating material, forming the support structures SH.

Referring to FIG. 13G, the sacrificial insulating layers 118 may be removed and gate electrodes 130 may be formed.

An isolation opening for opening a region corresponding to the isolation regions MS in FIG. 1 and FIG. 2B may be formed. The isolation opening may be formed by forming a plurality of vertical holes in a region in which isolation regions MS are formed, expanding the plurality of vertical holes through a cleaning process, or the like, and connecting to neighboring vertical holes. When the isolation opening is formed by expanding the plurality of vertical holes, the side surface of the isolation opening may continuously include outwardly curved surfaces, but an example embodiment thereof is not limited thereto.

The sacrificial insulating layers 118 exposed through the isolation openings may be removed. The sacrificial insulating layers 118 may be selectively removed, for example, using wet etching, with respect to the interlayer insulating layers 120, the channel structures CH, the dummy channel structures DCH, the through-insulating structures 165, the support structures SH, and the preliminary contact insulating layers 160P.

The gate electrodes 130 may be formed by depositing a conductive material on the regions from which the sacrificial insulating layers 118 are removed. The conductive material may include a metal, polycrystalline silicon, or a metal silicide material. In the gate electrodes 130, the diffusion barrier layers 131 (see FIG. 3A) maybe formed, and the conductive material may be deposited, thereby forming the gate electrodes 130. In some example embodiments, a portion of the channel dielectric layer 145 may be formed before the gate electrodes 130 are formed. Accordingly, a stack structure GS including first to third stack structures GS1-GS3 may be formed. After the gate electrodes 130 are formed, an insulating material may be deposited in the isolation openings, thereby forming isolation regions MS extending in the X-direction as illustrated in FIG. 1.

As illustrated in FIG. 14D, first and second insulating regions SS1 and SS2 penetrating the upper gate electrodes 130U may be formed. As illustrated in FIGS. 1 and 2B, trenches for removing the upper gate electrodes 130U and the interlayer insulating layer 120 in regions corresponding to the first and second insulating regions SS1 and SS2 may be formed.

Between two adjacent isolation regions MS, the trenches corresponding to the first insulating regions SS1 may be formed by selectively cutting an upper portion of the third stack structure GS3. These trenches penetrate the first to seventh upper gate electrodes 130U1-130U7 from an upper portion of the uppermost interlayer insulating layer 121, extending in the X-direction within the memory region R1 and the upper contact region R3. Similarly, trenches corresponding to the second insulating regions SS2 may be formed by selectively cutting an upper portion of the third stack structure GS3. These trenches also penetrate the first to seventh upper gate electrodes 130U1-130U7 from an upper portion of the uppermost interlayer insulating layer 121, but extend in the Y-direction between the upper contact region R3 and the extension region R2. The trenches may extend by cutting a portion of the channel structures CH in the memory region R1, and first and second insulating regions SS1 and SS2 may be formed by stacking insulating materials in each trench.

As illustrated in FIG. 13H, wordline contact structures MC2 may be formed.

Specifically, the contact sacrificial layers 129 in the extension region R2 may be selectively removed for the preliminary contact insulating layers 160P, and side surfaces and bottom surfaces of the preliminary contact insulating layers 160P may be exposed.

By performing an etch-back process, the bottom surfaces of the exposed preliminary contact insulating layers 160P may be removed.

Accordingly, the contact regions of the memory gate electrodes 130M or the lower gate electrodes 130L allocated to the bottom surface may be exposed. In the etch-back process, the gate electrodes 130 may function as etch stoppers, and anisotropic etching may be performed in the vertical direction through dry etching.

A conductive material may be deposited by filling the contact holes OP2, thereby forming the contact plugs 170. First, the contact barrier layers 171 may be formed along side surfaces and bottom surfaces of the contact holes OP2, and conductive material may be buried in the contact barrier layer 171, thereby forming the contact plugs 170. The contact plugs 170 may be physically connected to the gate electrodes 130 allocated below, respectively. When the entirety of the contact holes OP2 are filled, by performing a planarization process, the conductive material may be etched until the upper surface of the uppermost interlayer insulating layer 121 is exposed.

In this case, the planarization process may be performed through chemical mechanical polishing (CMP), and accordingly, the upper surface of the uppermost interlayer insulating layer 121 and the upper surface of the contact plugs 170 may both be coplanar with each other.

Referring to FIG. 13I, an upper interconnection structure may be formed on the stack structure GS.

An upper insulating layer 194 may be formed on the stack structure GS, and first to third studs 180a, 180b and 180c and cell interconnection lines 185 may be formed by penetrating the upper insulating layer 194.

The second and third studs 180b and 180c may be formed by forming stud holes penetrating the upper insulating layer 194 and exposing the contact plugs MC2, and filling the stud holes with a conductive material. The first studs 180a may be coaxial with a center axis l1 of the through-insulating structure 165 in the upper contact region R3, may penetrate the upper insulating layer 194 and the through-insulating structure 165, and may be in contact with the upper gate electrode 130U.

Accordingly, the first studs 180a may have a length longer than lengths of the second and third studs 180b and 180c.

The first studs 180a may be formed by forming stud holes penetrating the upper insulating layer 194 and the through-insulating structure 165, and filling the stud holes with a conductive material. The cell interconnection lines 185 may be formed on the studs 180a, 180b, and 180c. An insulating layer may be further formed on the cell interconnection lines 185, and a bonding structure for bonding with the second semiconductor structure in FIG. 9 may also be formed.

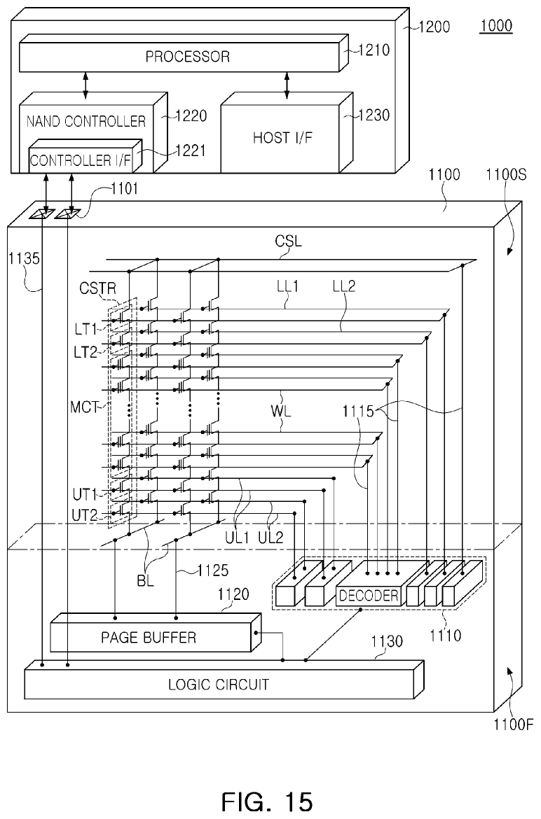

FIG. 15 is a diagram illustrating a data storage system including a semiconductor device according to example embodiments.

Referring to FIG. 15, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 12. The semiconductor device 1100 may include a first structure 1100F and a second structure 1100S on the first structure 1100F. In the example embodiments, the first structure 1100F may be disposed on the side of the second structure 1100S. The first structure 1100f may be configured as a peripheral circuit structure including a decoder circuit 1110, a page buffer 1120, and a logic circuit 1130. The second structure 1100S may be configured as a memory cell structure including bitline BL, common source line CSL, wordlines WL, first and second gate upper lines UL1 and UL2, first and second gate lower lines LL1 and LL2, and memory cell strings CSTR between the bitline BL and the common source line CSL.

In the second structure 1100S, each of the memory cell strings CSTR may include a plurality of memory cell transistors MCT disposed between lower transistors LT1 and LT2 adjacent to a common source line CSL, upper transistors UT1 and UT2 adjacent to a bitline BL, and lower transistors LT1 and LT2 and upper transistors UT1 and UT2. The number of lower transistors LT1 and LT2 and the number of upper transistors UT1 and UT2 may vary in example embodiments.

In example embodiments, the upper transistors UT1 and UT2 may include string select transistors, and the lower transistors LT1 and LT2 may include ground select transistors. The gate lower lines LL1 and LL2 may be configured as gate electrodes of the lower transistors LT1 and LT2, respectively. The wordlines WL may be configured as gate electrodes 130 of the memory cell transistors MCT, and the gate upper lines UL1 and UL2 may be configured as gate electrodes of the upper transistors UT1 and UT2, respectively.

In example embodiments, the lower transistors LT1 and LT2 may include a series-connected lower erase control transistor LT1 and a ground select transistor LT2. The upper transistors UT1 and UT2 may include a string select transistor UT1 and an upper erase control transistor UT2 connected to each other in series. At least one of the lower erase control transistor LT1 or the upper erase control transistor UT2 may be used for an erase operation of erasing data stored in the memory cell transistors MCT using the GIDL phenomenon.

Common source line CSL, first and second gate lower lines LL1 and LL2, wordlines WL, and first and second gate upper lines UL1 and UL2 may be electrically connected to the decoder circuit 1110 through first interconnections 1115 extending from the first structure 1100f to the second structure 1100S. The bitlines BL may be electrically connected to the page buffer 1120 through the second interconnections 1125 extending from the first structure 1100f to the second structure 1100S.

In the first structure 1100f, the decoder circuit 1110 and the page buffer 1120 may perform a control operation for at least one select memory cell transistor among a plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output interconnection 1135 extending from the first structure 1100f to the second structure 1100S.

The controller 1200 may include a processor 1210, a NAND controller 1220, and a host interface 1230. In example embodiments, the data storage system 1000 may include a plurality of semiconductor devices 1100, and in this case, the controller 1200 may control a plurality of semiconductor devices 1100.

The processor 1210 may control operations of the data storage system 1000 including the controller 1200. The processor 1210 may operate according to predetermined firmware and may access the semiconductor devices 1100 by controlling the NAND controller 1220. The NAND controller 1220 may include a controller interface 1221 handling communication with the semiconductor device 1100. Through the controller interface 1221, control commands for controlling the semiconductor device 1100, data to be written in the memory cell transistors MCT of the semiconductor device 1100, data to be read from the memory cell transistors MCT of the semiconductor device 1100, or the like, may be transmitted. The host interface 1230 may provide a communication function between the data storage system 1000 and an external host. When a control command is received from an external host through the host interface 1230, the processor 1210 may control the semiconductor device 1100 in response to the control command.

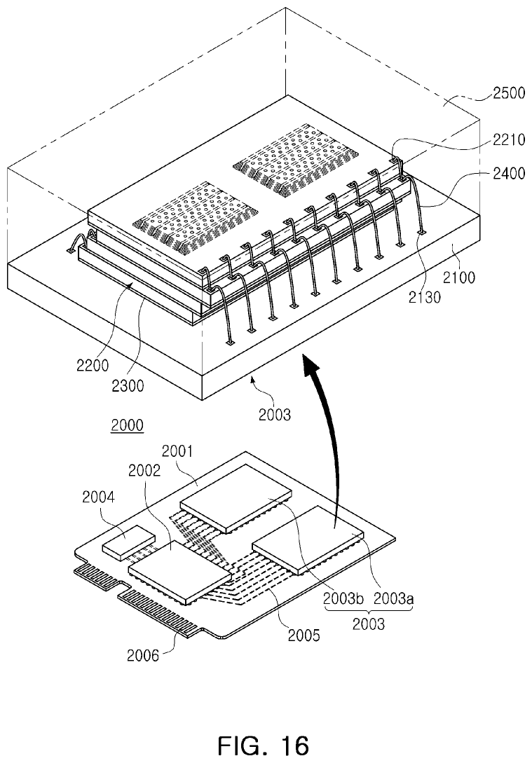

FIG. 16 is a perspective diagram illustrating a data storage system including a semiconductor device in example embodiments.

Referring to FIG. 16 a data storage system 2000 in an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a bonding structure 2400 electrically connecting the semiconductor chips 2200 to the package substrate 2100, and a molding layer 2500 covering the semiconductor chips 2200 and the bonding structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 15. Each of the semiconductor chips 2200 may include gate stack structures 3210 and channel structures 3220. Each of the semiconductor chips 2200 may include the semiconductor device described in the aforementioned example embodiment with reference to FIG. 1 to FIG. 12.

In the example embodiments, the bonding structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the bonding structure 2400 of a bonding wire method.

In the example embodiments, the controller 2002 and the semiconductor chips 2200 may be included in a single package. In an example embodiment, the controller 2002 and the semiconductor chips 2200 may be mounted on an interposer substrate different from the main board 2001, and the controller 2002 and the semiconductor chips 2200 may be connected to each other by interconnection formed on the interposer substrate.

According to the aforementioned example embodiments, when the upper gate electrodes include string select gate electrodes, a step structure of staircase form may not be formed in the string select gate electrodes, and a space for disposing string select contact plugs in the allocated string select gate electrodes may be formed through the insulating structure. Also, the insulating structure may be formed to expose the allocated string select gate electrodes through etching performed in multiple steps, similarly to a wordline select plug. Accordingly, the step structure of the staircase form and the dummy step structure of the gate electrodes may not be formed, such that the area of the memory cell region may be ensured, and high integration may thus be implemented.

Accordingly, the step structure of the staircase form may not be formed in the region in which the wordline contact structure is disposed, and also the step structure of the staircase form may not be formed in the region in which the string select contact plug is disposed, such that the process may be simplified.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a substrate including a first region, a second region and a third region between the first region and the second region;
a stack structure including gate electrodes including lower gate electrodes, memory gate electrodes and upper gate electrodes sequentially stacked and spaced apart from each other in a first direction perpendicular to an upper surface of the substrate, and interlayer insulating layers disposed alternately with the gate electrodes, in the first region, the second region and the third region;
a channel structure penetrating the stack structure and extending in the first direction in the first region;
support structures penetrating the stack structure and extending in the first direction in the third region;
first contact structures extending in the first direction by different lengths by penetrating an uppermost interlayer insulating layer among the interlayer insulating layers, or penetrating at least a portion of the upper gate electrodes, the first contact structures being electrically connected to the upper gate electrodes, respectively, in the third region; and
second contact structures extending from the uppermost interlayer insulating layer in the first direction by different lengths by penetrating the upper gate electrodes and at least a portion of the gate electrodes of the memory gate electrodes and the lower gate electrodes, the second contact structures being electrically connected to the lower gate electrodes and the memory gate electrodes, respectively, in the second region,
wherein each of the first contact structures includes:
a through-insulating structure extending in the first direction and penetrating the uppermost interlayer insulating layer or penetrating at least a portion of the upper gate electrodes and in contact with an upper surface of an allocated upper gate electrode among the upper gate electrodes; and
a first stud extending in the first direction by penetrating the through-insulating structure and in contact with the upper surface of the allocated upper gate electrode, and
wherein some of the support structures are in contact with at least a portion of the through-insulating structure.

2. The semiconductor device of claim 1, wherein the first stud is physically spaced apart from the support structures.

3. The semiconductor device of claim 1,
wherein the first contact structures are spaced apart from each other by a first spacing distance, and
wherein a portion of the stack structure is disposed in a spacing area between the first contact structures.

4. The semiconductor device of claim 3, wherein some of the support structures are disposed in the spacing area.

5. The semiconductor device of claim 1, wherein the support structures are dummy channel structures each having the same shape as a shape of the channel structure.

6. The semiconductor device of claim 1,
wherein the through-insulating structure includes:
an upper surface;
a lower surface in contact with the allocated upper gate electrode;
an inner side surface in contact with the first stud between the upper surface and the lower surface; and
an outer side surface in contact with the interlayer insulating layers and/or the upper gate electrodes, and
wherein a side surface of the first stud is physically spaced apart from the interlayer insulating layers and the upper gate electrodes.

7. The semiconductor device of claim 6, wherein an upper surface of the stack structure is coplanar with the upper surface of the through-insulating structure.

8. The semiconductor device of claim 6, wherein an upper surface of the first stud is positioned at a level higher than a level of the upper surface of the through-insulating structure.

9. The semiconductor device of claim 6, wherein a width of an upper surface of the first stud is less than ⅓ to ¼ of a width of the upper surface of the through-insulating structure.

10. The semiconductor device of claim 6, wherein an upper surface of the support structures is coplanar with the upper surface of the through-insulating structure.

11. The semiconductor device of claim 6, wherein at least one of the support structures is disposed between the inner side surface and the outer side surface of the through-insulating structure.

12. The semiconductor device of claim 1, wherein ½ or less of a diameter of at least one of the support structures protrudes into the through-insulating structure.

13. The semiconductor device of claim 1, wherein the semiconductor device further includes:
first insulating regions penetrating the upper gate electrodes in the first region and the third region, extending in a second direction perpendicular to the first direction, and spaced apart from each other in a third direction perpendicular to the first and second directions; and
a second insulating region connected to the first insulating regions, penetrating the upper gate electrodes between the third region and the second region, and extending in the third direction.

14. The semiconductor device of claim 1, wherein each of the second contact structures includes:
a contact plug penetrating the stack structure and in contact with an upper surface of an allocated gate electrode among the lower gate electrodes and the memory gate electrodes; and
a side insulating layer surrounding a side surface of the contact plug and disposed between the stack structure and the contact plug.

15. The semiconductor device of claim 14, wherein a thickness of the through-insulating structure is greater than a thickness of the side insulating layer.

16. A semiconductor device, comprising:
a substrate including a first region, a second region and a third region between the first region and the second region;
a stack structure including gate electrodes including lower gate electrodes, memory gate electrodes and upper gate electrodes sequentially stacked and spaced apart from each other in a first direction perpendicular to an upper surface of the substrate, and interlayer insulating layers disposed alternately with the gate electrodes, in the first region, the second region and the third region;
a channel structure penetrating the stack structure and extending in the first direction in the first region;
support structures penetrating the stack structure, extending in the first direction in the third region, and spaced apart from each other by a first distance;
first contact structures extending in the first direction by different lengths by penetrating an uppermost interlayer insulating layer among the interlayer insulating layers, or penetrating at least a portion of the upper gate electrodes, the first contact structures being electrically connected to the upper gate electrodes, respectively, and having an upper surface having a first width, in the third region; and
second contact structures extending from the uppermost interlayer insulating layer in the first direction by different lengths by penetrating the upper gate electrodes, and at least a portion of the gate electrodes of the memory gate electrodes and the lower gate electrodes, the second contact structures being electrically connected to the lower gate electrodes and the memory gate electrodes, respectively, in the second region, and
wherein the first width of the first contact structures is greater than the first distance.

17. The semiconductor device of claim 16,
wherein each of the first contact structures includes:
a through-insulating structure extending in the first direction and penetrating the uppermost interlayer insulating layer or penetrating at least a portion of the upper gate electrodes, and in contact with an upper surface of an allocated upper gate electrode among the upper gate electrodes; and
a first stud extending in the first direction, penetrating the through-insulating structure and in contact with the upper surface of the allocated upper gate electrode, and
wherein the support structures are spaced apart from the first stud.

18. The semiconductor device of claim 16,
wherein the first contact structures are spaced apart from each other by a second distance, and
wherein a portion of the support structures is disposed within the second distance.

19. The semiconductor device of claim 16, further comprising:
a shared through-insulating structure that commonly surrounds a plurality of first studs of the first contact structures,
wherein the plurality of first studs penetrating the shared through-insulating structure are in contact with the same upper gate electrode among the upper gate electrodes.

20. A data storage system, comprising:
a semiconductor storage device including a first semiconductor structure including circuit devices, a second semiconductor structure disposed on one surface of the first semiconductor structure, and an input/output pad electrically connected to the circuit devices; and
a controller electrically connected to the semiconductor storage device through the input/output pad and controlling the semiconductor storage device,
wherein the second semiconductor structure includes:
a substrate including a first region, a second region and a third region between the first region and the second region;
a stack structure including gate electrodes including lower gate electrodes, memory gate electrodes and upper gate electrodes sequentially stacked and spaced apart from each other in a first direction perpendicular to an upper surface of the substrate, and interlayer insulating layers disposed alternately with the gate electrodes, in the first region, the second region and the third region;
a channel structure penetrating the stack structure and extending in the first direction in the first region;
support structures penetrating the stack structure, extending in the first direction, and spaced apart from each other by a first distance, in the third region;
first contact structures extending in the first direction by different lengths by penetrating an uppermost interlayer insulating layer among the interlayer insulating layers, or penetrating at least a portion of the upper gate electrodes, the first contact structures being electrically connected to the upper gate electrodes, respectively, and having an upper surface having a first width, in the third region; and
second contact structures extending from the uppermost interlayer insulating layer in the first direction by different lengths by penetrating the upper gate electrodes, and at least a portion of the gate electrodes of the memory gate electrodes and the lower gate electrodes, the second contact structures being electrically connected to the lower gate electrodes and the memory gate electrodes, respectively, in the second region,
wherein the first width of the first contact structures is greater than the first distance.
